(19) United States
(12) Patent Application Publication
(10) Pub. No.: US 2025/0374516 A1
(43) Pub. Date: Dec. 4, 2025

(54) 3-DIMENSIONAL MEMORY DEVICE

(71) Applicant: Korea Advanced Institute of Science and Technology, Daejeon (KR)

(72) Inventors: Seong Hwan CHO, Daejeon (KR); Dong Hwan KIM, Daejeon (KR); Gi Woo LEE, Daejeon (KR)

(21) Appl. No.: 19/212,154

(22) Filed: May 19, 2025

(30) Foreign Application Priority Data
May 31, 2024 (KR) 10-2024-0071920

(51) Int. Cl. H10B 12/00

(52) U.S. Cl. CPC H10B 12/30

(57) ABSTRACT

A 3-dimensional memory device, including: memory cell slots deployed in a first horizontal direction, wherein each of the memory cell slot includes: memory cells deployed in a second horizontal direction and in a vertical direction; first access lines arranged in the vertical direction and deployed in the second horizontal direction, wherein the first access lines are one type of lines among (i) wordlines connected to each of gate terminals of each of the memory cells and (ii) bitlines connected to each of drain terminals of each of the memory cells; and second access lines arranged in the second horizontal direction and deployed in the vertical direction, wherein the second access lines are a different type of lines among (i) wordlines connected to each of the gate terminals of each of the memory cells and (ii) bitlines connected to each of the drain terminals of each of the memory cells.

### CROSS REFERENCE OF RELATED APPLICATION

This present application claims the benefit of the earlier filing date of Korean non-provisional patent application No. 10-2024-0071920, filed on May 31, 2024, the entire contents of which being incorporated herein by reference.

### FIELD OF THE DISCLOSURE

The present disclosure relates to a 3-dimensional memory device; and more particularly, the 3-dimensional memory device with a high degree of integration and small delay time when data is being read.

### BACKGROUND OF THE DISCLOSURE

Currently, high degree of integration through miniaturization of memory cells in a memory device technology has reached its limit.

In order to solve this problem, researches and developments into 3-dimensional memory device technologies are being conducted.

Some 3-dimensional memory device technologies include (1) HBM (i.e., High-Bandwidth Memory), which stacks multiple substrates composed of a single-layer memory cell array and connects them with TSV (i.e., Through-Silicon Vias), and (2) Monolithic 3D DRAM, which forms memory cells in a stacked array structure within a single substrate.

FIGS. 1A to 1D are drawings schematically illustrating a conventional 3-dimensional memory device. For an ease of explanation, FIGS. 1A to 1C only illustrate one memory cell slot including 16 memory cells, and FIG. 1D illustrates only two memory cell slots.

First, by referring to FIG. 1A to 1C, each of memory cells having each of capacitors arranged in a first horizontal direction D1 may be deployed in a second horizontal direction D2 that is orthogonal to the first horizontal direction D1 and a vertical direction D3.

Further, each of wordlines WL #1, WL #2, WL #3, and WL #4 arranged in the vertical direction D3 may be deployed in the second horizontal direction D2, and each of bitlines BL #1, BL #2, BL #3, and BL #4 arranged in the second horizontal direction D2 may be deployed in the vertical direction D3.

Herein, each of the wordlines WL #1, WL #2, WL #3, and WL #4 may be connected to each of gate terminals of the memory cells deployed at their corresponding same relative second horizontal directional positions. Further, each of the bitlines BL #1, BL #2, BL #3, and BL #4 may be connected to each of drain terminals of the memory cells deployed at their corresponding same relative vertical directional positions.

Moreover, by referring to FIG. 1D, it can be seen that each of memory cell slots Slot #1 and Slot #2 that are illustrated in FIGS. 1A to 1C may be deployed in the first horizontal direction D1. Further, for each of the memory slots Slot #1 and Slot #2, each of the wordlines WL #1, WL #2, WL #3, and WL #4 arranged in the vertical direction D3 may be connected to each of sub-wordline drivers of a sub-wordline driver array SWD Array positioned below each of the wordlines WL #1, WL #2, WL #3, and WL #4. Meanwhile, for each of the memory cell slots Slot #1 and Slot #2, each of the bitlines BL #1, BL #2, BL #3, and BL #4 arranged in the second horizontal direction D2 may be extended to a sense amplifier array SA Array and connected to each of sense amplifiers through each of vias. Herein, the bitlines of a single memory cell slot, which extend to the sense amplifier array SA Array in order to connect to each of the sense amplifiers through the vias, may form a step shape. That is, each of extended portions of each of the bitlines connected to each of the vias in a region of the sense amplifier array SA Array may be located at different vertical position (i.e., level) from each other in the vertical direction D3.

In such a conventional 3-dimensional memory device, a degree of integration of the conventional 3-dimensional memory device is determined by a sum of an area of the sub-wordline driver array and an area of the sense amplifier array, and not by an area of the memory cells from a planar view.

Therefore, in order to increase the degree of integration of the conventional 3-dimensional memory device, the sum of (1) an area of a plurality of sub-wordline driver arrays from the planar view and (2) the area of the memory cells from the planar view should be as small as possible.

However, if a same-size manufacturing process is used for (i) a logic manufacturing process used to form the sub-wordline driver arrays and the sense amplifier array, and (ii) a memory manufacturing process used to form the memory cells, then, generally, the areas of the sub-wordline driver and the sense amplifier from the planar view will be larger than an area of a unit memory cell from the planar view.

Therefore, when a memory device is manufactured by using a same manufacturing process, the area of the sub-wordline driver array and the area of the sense amplifier array from the planar view become larger than the area of the memory cells from the planar view, which may cause a decrease in the degree of integration of the memory device.

Moreover, in order to increase the degree of integration of the memory device, the logic manufacturing process whose size is smaller than the memory manufacturing process is used to decrease the area of the sub-wordline driver array and the area of the sense amplifier array, and then the memory slots formed by using the memory manufacturing process are connected to logic arrays through heterojunction. However, this process has a problem of incurring additional costs.

Meanwhile, the above description relates to the conventional 3-dimensional memory device in which wordlines are arranged in the vertical direction, however, the same problem also exists for the conventional 3-dimensional memory device in which bitlines are arranged in the vertical direction.

### PRIOR ART LITERATURE

(1) Korean Patent Registration No. 10-2237739
(2) Korean Patent Registration No. 10-2368332
(3) Korean Patent Publication No. 10-2021-0102094

### SUMMARY OF THE DISCLOSURE

It is an object of the present disclosure to solve all the aforementioned problems.

It is another object of the present disclosure to provide a 3-dimensional memory device with an increased degree of integration.

It is still another object of the present disclosure to provide the 3-dimensional memory device with the increased degree of integration by reducing a sum of area of a sub-wordline driver array and a sense amplifier array.

It is still yet another object of the present disclosure to provide the 3-dimensional memory device with a reduced area of the sub-wordline driver array and/or the sense amplifier array by allowing one of sub-wordline drivers and/or one of the sense amplifiers to share a plurality of bitlines and/or a plurality of wordlines.

It is still yet another object of the present disclosure to provide the 3-dimensional memory device that shares the bitlines through the sense amplifier without time delays in a read operation.

In accordance with one aspect of the present disclosure, there is provided a 3-dimensional memory device, including: a first memory cell slot to an n-th memory cell slot deployed in a first horizontal direction, wherein n is an integer greater than or equal to 2, wherein each of the first memory cell slot to the n-th memory cell slot includes: memory cells deployed in a second horizontal direction orthogonal to the first horizontal direction and deployed in a vertical direction; first access lines, each of which is arranged in the vertical direction and each of which is deployed in the second horizontal direction, wherein the first access lines are determined as one type of lines among (i) wordlines connected to each of gate terminals of each of the memory cells deployed in the vertical direction and (ii) bitlines connected to each of drain terminals of each of the memory cells deployed in the vertical direction; and second access lines, each of which is arranged in the second horizontal direction and each of which is deployed in the vertical direction, wherein the second access lines are determined as a different type of lines among (i) wordlines connected to each of the gate terminals of each of the memory cells deployed in the second horizontal direction and (ii) bitlines connected to each of the drain terminals of each of the memory cells deployed in the second horizontal direction; wherein (i) (i-1) at least two of the first access lines among the first access lines of the first memory cell slot to the first access lines of the n-th memory cell slot deployed at their corresponding same relative second horizontal directional positions are connected to first global lines arranged in the first horizontal direction, wherein the first global lines are connected to one type of circuit elements among each of sub-wordline drivers of a first circuit array positioned below the first memory cell slot to the n-th memory cell slot and each of sense amplifiers of the first circuit array, and (i-2) the second access lines of the first memory cell slot to the second access lines of the n-th memory cell slot deployed at their corresponding same relative vertical directional positions are (i-2-1) extended to a second circuit array positioned at an outer side region of the first memory cell slot to the n-th memory cell slot and (i-2-2) connected to a different type of circuit elements among each of the sub-wordline drivers of the second circuit array and each of the sense amplifiers of the second circuit array through vias deployed in the first horizontal direction, and (ii) (ii-1) the first access lines of the first memory cell slot to the first access lines of the n-th memory cell slot deployed at their corresponding same relative second horizontal directional positions are connected to one type of circuit elements among each of the sub-wordline drivers of the first circuit array and each of the sense amplifiers of the first circuit array, and (ii-2) at least two of the second access lines among the second access lines of the first memory cell slot to the second access lines of the n-th memory cell slot deployed at their corresponding same relative vertical directional positions are (ii-2-1) extended to the second circuit array and (ii-2-2) connected to second global lines arranged in the first horizontal direction through the vias deployed in the first horizontal direction, wherein the second global lines are connected to a different type of the circuit elements among each of the sub-wordline drivers of the second circuit array and each of the sense amplifiers of the second circuit array.

As one example in case the first access lines or the second access lines are the wordlines, each of the first global lines is (i) deployed at a side region of a first horizontal directional region on the first circuit array, which is defined by the first access lines of the first memory slot to the first access lines of the n-th memory slot deployed at their corresponding same relative second horizontal directional positions, and (ii) connected to each of corresponding said first access lines, and each of the second global lines is (i) deployed at a side region of a first horizontal directional region on the second circuit array, which is defined by the vias corresponding to the second access lines of the first memory cell slot to the second access lines of the n-th memory cell slot deployed at their corresponding same relative vertical directional positions, and (ii) connected to each of corresponding said vias.

As one example, in case the first access lines or the second access lines are the wordlines, each of the first global lines includes (i) first body lines deployed at a side region of a first horizontal directional region on the first circuit array, which is defined by the first access lines of the first memory slot to the first access lines of the n-th memory slot deployed at their corresponding same relative second horizontal directional positions, and (ii) first contact pads extended in the second horizontal direction from each of the first body lines and connected to each of corresponding said first access lines, and each of the second global lines includes (i) second body lines deployed at a side region of a first horizontal directional region on the second circuit array, which is defined by the second access lines of the first memory slot to the second access lines of the n-th memory slot deployed at their corresponding same relative vertical directional positions, and (ii) second contact pads extended in the second horizontal direction from each of the second body lines and connected to each of corresponding said vias.

As one example, in case the first access lines or the second access lines are the wordlines, each of the first global lines is alternately deployed at one side region and an opposite side region of a first horizontal directional region on the first circuit array, which is defined by the first access lines of the first memory slot to the first access lines of the n-th memory slot deployed at their corresponding same second relative horizontal directional positions, and each of the second global lines is alternatively deployed at one side region and an opposite side region of a first horizontal directional region on the second circuit array, which is defined by the vias corresponding to the second access lines of the first memory cell slot to the second access lines of the n-th memory cell slot deployed at their corresponding same relative vertical directional positions.

As one example, in case the first access lines or the second access lines are the bitlines, each of the first global lines is connected directly or connected through switches to at least two first access lines among the first access lines of the first memory cell slot to the first access lines of the n-th memory cell slot deployed at their corresponding same relative second horizontal directional positions, and each of the second global lines is connected directly or connected via the switches to at least two vias corresponding to at least two second access lines among the second access lines of the first memory cell slot to the second access lines of the n-th memory cell slot deployed at their corresponding same relative vertical directional positions.

As one example, in case the first access lines or the second access lines are the bitlines, each of the first global lines includes (i) first body lines deployed at a side region of a first horizontal directional region on the first circuit array, which is defined by the first access lines of the first memory slot to the first access lines of the n-th memory slot deployed at their corresponding same relative second horizontal directional positions, and (ii) first contact pads extended in the second horizontal direction from each of the first body lines and connected to each of corresponding said first access lines, and each of the second global lines includes (i) second body lines deployed at a side region of a first horizontal directional region on the second circuit array, which is defined by the second access lines of the first memory slot to the second access lines of the n-th memory slot deployed at their corresponding same relative vertical directional positions, and (ii) second contact pads extended in the second horizontal direction from each of the second body lines and connected to each of corresponding said vias.

As one example, in case the first access lines or the second access lines are the bitlines, each of the first global lines is alternately deployed at one side region and an opposite side region of a first horizontal directional region on the first circuit array, which is defined by the first access lines of the first memory slot to the first access lines of the n-th memory slot deployed at their corresponding same relative second horizontal directional positions, and each of the second global lines is alternatively deployed at one side region and an opposite side region of a first horizontal directional region on the second circuit array, which is defined by the vias corresponding to the second access lines of the first memory cell slot to the second access lines of the n-th memory cell slot deployed at their corresponding same relative vertical directional positions.

In accordance with another aspect of the present disclosure, there is provided a 3-dimensional memory device, including: a first memory cell slot to an n-th memory cell slot deployed in a first horizontal direction, wherein n is an integer greater than or equal to 2, wherein each of the first memory cell slot to the n-th memory cell slot includes: memory cells deployed in a second horizontal direction orthogonal to the first horizontal direction and deployed in a vertical direction; first access lines, each of which is arranged in the vertical direction and each of which is deployed in the second horizontal direction, wherein the first access lines are determined as one type of lines among (i) wordlines connected to each of gate terminals of each of the memory cells deployed in the vertical direction and (ii) bitlines connected to each of drain terminals of each of the memory cells deployed in the vertical direction; and second access lines, each of which is arranged in the second horizontal direction and each of which is deployed in the vertical direction, wherein the second access lines are determined as a different type of lines among (i) wordlines connected to each of the gate terminals of each of the memory cells deployed in the second horizontal direction and (ii) bitlines connected to each of the drain terminals of each of the memory cells deployed in the second horizontal direction; wherein (i-1) at least two of the first access lines among the first access lines of the first memory cell slot to the first access lines of the n-th memory cell slot deployed at their corresponding same relative second horizontal directional positions are connected to first global lines arranged in the first horizontal direction, wherein the first global lines are connected to one type of circuit elements among each of sub-wordline drivers of a first circuit array positioned below the first memory cell slot to the n-th memory cell slot and each of sense amplifiers of the first circuit array, and (i-2) at least two of the second access lines among the second access lines of the first memory cell slot to the second access lines of the n-th memory cell slot deployed at their corresponding same relative vertical directional positions are (i-2-1) extended to a second circuit array positioned at an outer side region of the first memory cell slot to the n-th memory cell slot and (i-2-2) connected to second global lines arranged in the first horizontal direction through the vias deployed in the first horizontal direction, wherein the second global lines are connected to a different type of circuit elements among each of the sub-wordline drivers of the second circuit array and each of the sense amplifiers of the second circuit array.

As one example, in case the first access lines that are deployed at a corresponding specific c same relative second horizontal directional position in the first horizontal direction, among the first access lines of the first memory cell slot to the first access lines of the n-th memory cell slot deployed at their corresponding same relative second horizontal directional positions, are defined as a (1_1)-st access line to a (1_n)-th access line, each of the first global lines shares m first access lines, which are sequentially adjacent access lines, among the (1_1)-st access line to the (1_n)-th access line, with m being an integer greater than or equal to 2, and wherein, in case the second access lines that are deployed at a corresponding specific same relative vertical directional position, among the second access lines of the first memory cell slot to the second access lines of the n-th memory cell slot deployed at their corresponding relative same vertical directional positions, are defined as a (2_1)-st access line to a (2_n)-th access line, each of the second global lines shares n/m second access lines, which are sequentially m-th adjacent access lines, among the (2_1)-st access line to the (2_n)-th access line.

As one example, n is a multiple of m, wherein the first global lines include a (1_1)-st global line to a (1_(n/m))-th global line, wherein a (1_j)-th global line shares a (1_(1+(j−1)*m))-th access line to a (1_j*m)-th access line, with j being an integer greater than or equal to 1 and less than or equal to n/m, wherein the second global lines include a (2_1)-st global line to a (2_m)-th global line, wherein a (2_k)-th global line shares a (2_(k+(s−1)*m))-th access line, with k being an integer greater than or equal to 1 and less than or equal to m, and with s being integers greater than or equal to 1 and less than or equal to n/m.

As one example, n is not a multiple of m, and (i) the first global lines include a (1_1)-st global line to a (1_[n/m])-th global line, with the [n/m] being a Gaussian function representing a maximum integer not greater than n/m, wherein, a (1_j)-th global line shares a (1_(1+(j−1)*m))-th access line to a (1_j*m)-th access line, with j being an integer greater than or equal to 1 and less than or equal to [n/m], wherein the second global lines include a (2_1)-st global line to a (2_m)-th global line, wherein a (2_k)-th global line shares a (2_(k+(s−1)*m))-th access line, with k being an integer greater than or equal to 1 and less than or equal to m, and with s being integers greater than or equal to 1 and less than or equal to [n/m], and (ii) (ii-1) a (1_(m*[n/m]+1))-th access line to the (1_n)-th access line, which exclude the (1_1)-st access line to a (1_(m*[n/m]))-th access line among the (1_1)-st access line to the (1_n)-th access line, wherein the (1_1)-st access line to the (1_(m*[n/m]))-th access line are being shared, and (ii-2) a (2_(m*[n/m]+1))-th access line to the (2_n)-th access line, which exclude the (2_1)-st access line to a (2_(m*[n/m]))-th access line among the (2_1)-st access line to the (2_n)-th access line, wherein the (2_1)-st access line to the (2_(m*[n/m]))-th access line are being shared, are shared by using a process of (i) with m being replaced by m′ or the (1_(m*[n/m]+1))-th access line to the (1_n)-th access line and the (2_(m*[n/m]+1))-th access line to the (2_n)-th access line are not shared.

As one example, each of the first global lines is formed at a lower region of the m first access lines that are sequentially adjacent, among the (1_1)-st access line to the (1_n)-th access line, and connected to each of the m first access lines that are sequentially adjacent, and each of the second global lines includes second body lines deployed at a lower side region of a first horizontal directional region, which is defined by a first via to an n-th via corresponding to the (2_1)-st access line to the (2_n)-th access line, and second contact pads extending in the second horizontal direction from each of the second body lines, wherein the second contact pads are connected to n/m vias, which are sequentially m-th adjacent vias, among the first via to the n-th via.

As one example, in case the first access lines are the bitlines, each of the first global lines is formed at a lower region of the m first access lines that are sequentially adjacent, among the (1_1)-st access line to the (1_n)-th access line, and is connected directly or connected through switches to each of the m first access lines that are sequentially adjacent, and wherein, in case the second access lines are the bitlines, each of the second global lines is connected directly or connected through switches to each of the n/m vias, which are sequentially m-th adjacent vias, among the first via to the n-th via.

As one example, each of the second body lines corresponding to each of the second global lines is alternatively deployed at one side region and an opposite side region of a first horizontal directional region, which is defined by the first via to the n-th via.

As one example, in case the second access lines that are deployed at a corresponding specific same relative vertical directional position, among the second access lines of the first memory cell slot to the second access lines of the n-th memory cell slot deployed at their corresponding same relative vertical directional positions, are defined as a (2_1)-st access line to a (2_n)-th access line, each of the second global lines shares m second access lines among the (2_1)-st access line to the (2_n)-th access line, wherein the m second access s lines are sequentially adjacent access lines, with m being an integer greater than or equal to 2, and wherein, in case the first access lines that are deployed at a corresponding specific same relative second horizontal directional position, among the first access lines of the first memory cell slot to the first access lines of the n-th memory cell slot deployed at their corresponding same relative second horizontal directional positions, are defined as a (1_1)-st access line to the (1_n)-th access line, each of the first global lines shares n/m first access lines, which are sequentially m-th adjacent access lines, among the (1_1)-st access line to the (1_n)-th access line.

As one example, n is a multiple of m, wherein the second global lines include a (2_1)-st global line to a (2_(n/m))-th global line, wherein a (2_j)-th global line shares a (2_(1+(j−1)*m))-th access line to a (2_j*m)-th access line, with j being an integer greater than or equal to 1 and less than or equal to n/m, wherein the first global lines include a (1_1)-st global line to a (1_m)-th global line, wherein a (1_k)-th global line shares a (1_(k+(s−1)*m))-th access line, with k being an integer greater than or equal to 1 and less than or equal to m, and with s being integers greater than or equal to 1 and less than or equal to n/m.

As one example, n is not a multiple of m, and (i) the second global lines include a (2_1)-st global line to a (2_[n/m])-th global line, the with [n/m] being a Gaussian function representing a maximum integer not greater than n/m, wherein a (2_j)-th global line shares a (1_(1+(j−1)*m))-th access line to a (1_j*m)-th access line, with j being an integer greater than or equal to 1 and less than or equal to the [n/m], wherein the first global lines include a (1_1)-st global line to a (1_m)-th global line, wherein a (1_k)-th global line shares a (1_(k+(s−1)*m))-th access line, with k being an integer greater than or equal to 1 and less than or equal to m, and with s being integers greater than or equal to 1 and less than or equal to [n/m], and (ii) (ii-1) a (2_(m*[n/m]+1))-th access line to the (2_n)-th access line, which exclude the (2_1)-st access line to a (2_(m*[n/m]))-th access line among the (2_1)-st access line to the (2_n)-th access line, wherein the (2_1)-st access line to the (2_(m*[n/m]))-th access line are being shared, and (ii-2) a (1_(m*[n/m]+1))-th access line to the (1_n)-th access line, which exclude the (1_1)-st access line to a (1_(m*[n/m]))-th access line among the (1_1)-st access line to the (1_n)-th access line, wherein the (1_1)-st access line to the (1_(m*[n/m]))-th access line are being shared, are shared by using a process of (i) with m being replaced by m′ or the (2_(m*[n/m]+1))-th access line to the (2_n)-th access line and the (1_(m*[n/m]+1))-th access line to the (1_n)-th access line are not shared.

As one example, each of the second global lines is formed at a lower region of m vias that are sequentially adjacent, among a first via to an n-th via corresponding to the (2_1)-st access line to the (2_n)-th access line, and connected to each of the m vias that are sequentially adjacent, and each of the first global lines includes first body lines formed at a lower side region of a first horizontal directional region, which is defined by the (1_1)-st access line to the (1_n)-th access line, and first contact pads extending in the second horizontal direction from each of the first body lines, wherein the first contact pads are connected to the n/m first access lines, which are sequentially m-th adjacent access lines, among the (1_1)-st access line to the (1_n)-th access line.

As one example, in case the second access lines are the bitlines, each of the second global lines is formed at a lower region of the m vias that are sequentially adjacent, among the first via to the n-th via, and is connected directly or connected through switches to each of the m vias that are sequentially adjacent, and wherein, in case the first access lines are the bitlines, each of the first global lines is connected directly or connected through switches to each of the n/m first access lines, which are sequentially m-th adjacent access lines, among the (1_1)-st access line to the (1_n)-th access line.

As one example, each of the first body lines corresponding to each of the first global lines is alternatively deployed at one side region and an opposite side region of the first horizontal directional region, which is defined by the (1_1)-st access line to the (1_n)-th access line.

### BRIEF DESCRIPTION OF THE DRAWINGS

The following drawings to be used to explain example embodiments of the present disclosure are only part of example embodiments of the present disclosure and other drawings can be obtained based on the drawings by those skilled in the art of the present disclosure without inventive work.

FIGS. 1A to 1D are drawings schematically illustrating a conventional 3-dimensional memory device.

FIG. 2 is a drawing schematically illustrating a 3-dimensional memory device in accordance with one example embodiment of the present disclosure.

FIGS. 3A to 3C are drawings schematically illustrating a unit memory cell slot of the 3-dimensional memory device in accordance with one example embodiment of the present disclosure.

FIG. 4 is a drawing schematically illustrating the 3-dimensional memory device in accordance with another example of the 3-dimensional memory device.

FIGS. 5A to 5C are drawings schematically illustrating a unit memory cell slot of the 3-dimensional memory device in accordance with another example of the 3-dimensional memory device.

FIG. 6 is a drawing schematically illustrating the 3-dimensional memory device that shares wordlines in accordance with one example of the 3-dimensional memory device.

FIGS. 7A to 7E are drawings schematically illustrating first global lines that share the wordlines of FIG. 6.

FIG. 8 is a drawing schematically illustrating the 3-dimensional memory device that shares bitlines in accordance with another example of the 3-dimensional memory device.

FIGS. 9A to 9B are drawings schematically illustrating the first global lines that share the bitlines of FIG. 8.

FIG. 10 is a drawing schematically illustrating the 3-dimensional memory device that shares the bitlines in accordance with one example embodiment of the present disclosure.

FIGS. 11A to 11B are drawings schematically illustrating second global lines that share the bitlines of FIG. 10.

FIG. 12 is a drawing schematically illustrating the 3-dimensional memory device that shares the wordlines in accordance with another example of the 3-dimensional device.

FIG. 13 is a drawing schematically illustrating the second global lines that share the worldlines in FIG. 12.

FIG. 14A to FIG. 15 are drawings schematically illustrating the 3-dimensional memory device that shares first access lines and second access lines in accordance with one example of the 3-dimensional device.

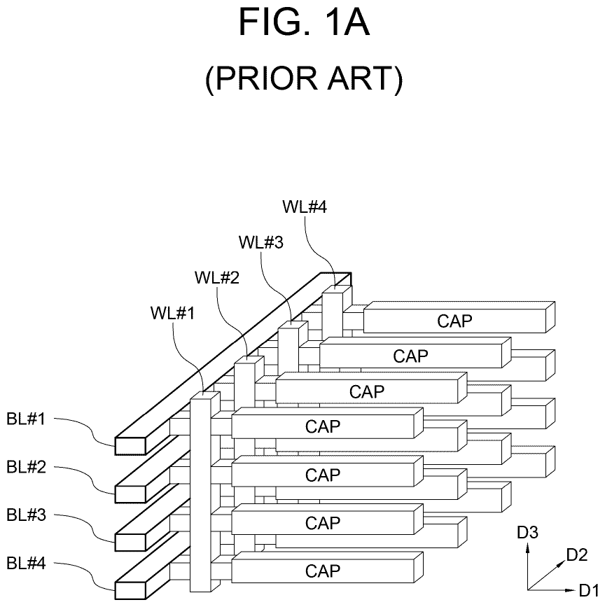

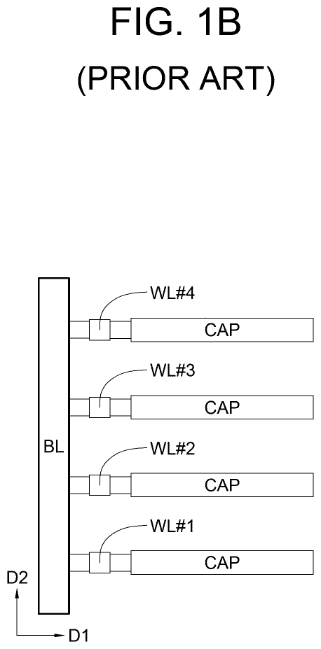

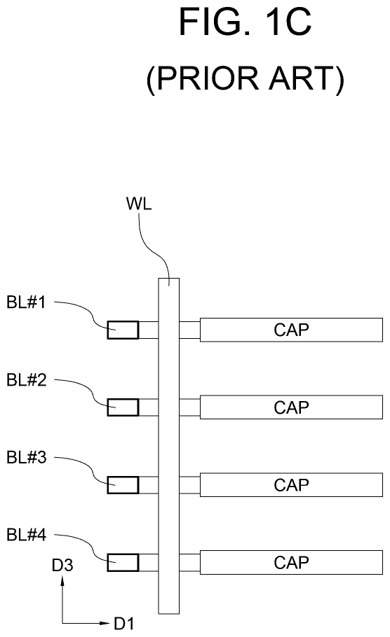

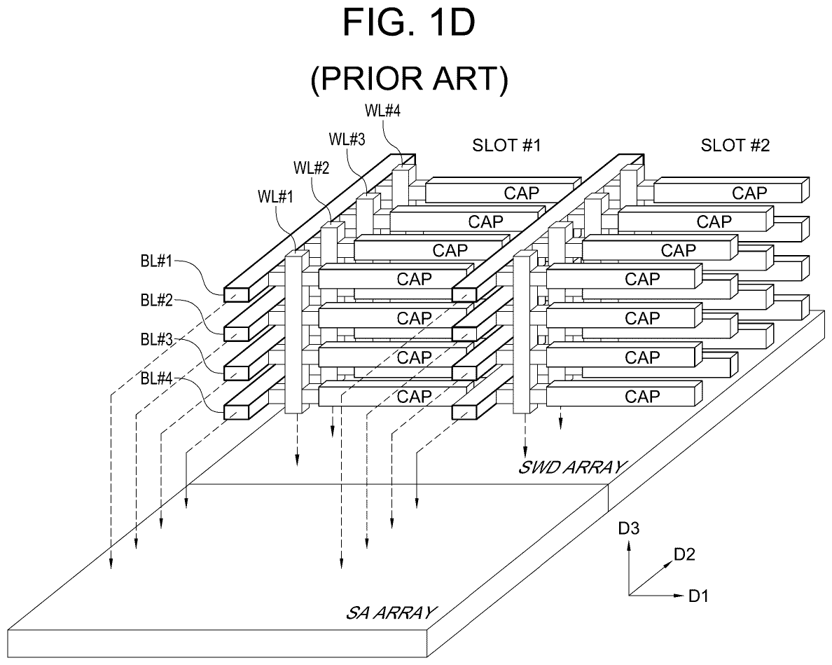

### DETAILED DESCRIPTION OF THE PREFERRED EMBODIMENTS

Detailed explanations on the present disclosure to be made below refer to attached drawings and diagrams illustrated as specific embodiment examples under which the present disclosure may be implemented to make clear of purposes, technical solutions, and advantages of the present disclosure. These embodiments are described in sufficient detail to enable those skilled in the art to practice the disclosure. It is to be understood that the various embodiments of the present disclosure, although different, are not necessarily mutually exclusive. For example, a particular feature, structure, or characteristic described herein in connection with one embodiment may be implemented within other embodiments without departing from the spirit and scope of the present disclosure. In addition, it is to be understood that the position or arrangement of individual elements within each disclosed embodiment may be modified without departing from the spirit and scope of the present disclosure. The following detailed description is, therefore, not to be taken in a limiting sense, and the scope of the present disclosure is defined only by the appended claims, appropriately interpreted, along with the full range of equivalents to which the claims are entitled. In the drawings, like numerals refer to the same or similar functionality throughout the several views.

To allow those skilled in the art to carry out the present disclosure easily, the example embodiments of the present disclosure by referring to attached drawings will be explained in detail. A memory device according to the present invention may be a RAM (i.e., Random Access Memory) such as a DRAM (i.e., Dynamic Random Access Memory), an SDRAM (i.e., Synchronous DRAM), an SRAM (i.e., Static Ram), a DDR SDRAM (i.e., Double Date Rate SDRAM), a DDR2 SDRAM, a DDR3 SDRAM, a PRAM (i.e., Phase change RAM), an MRAM (i.e., Magnetic RAM), a RRAM (i.e., Resistive RAM), etc., and the following description will focus on DRAM. Additionally, a memory cell may include a switching element that is switched by a wordline signal and a cell capacitor that stores charges, but for a convenience of explanation, the cell capacitor may also be referred to as the memory cell. Further, in the following description “A arranged in B” will refer to A being extended toward a direction of B, and “Cs deployed in D” will refer to a plurality of Cs positioned by following a direction of D. That is, “A arranged in B” will refer to A being formed in the direction of B, and “Cs deployed in D” will refer to a plurality of Cs being positioned in the direction of D such that a relative position of one of Cs and same relative positions of its adjacent Cs are positioned following the direction of D.

### First Example Embodiment

According to the present disclosure, a 3-dimensional memory device may include a first memory cell slot to an n-th memory cell slot deployed in a first horizontal direction. Herein, n is an integer greater than or equal to 2.

Further, each of the first memory cell slot to the n-th memory cell slot may include: memory cells deployed in a second horizontal direction orthogonal to the first horizontal direction and deployed in a vertical direction; first access lines, each of which is arranged in the vertical direction and each of which is deployed in the second horizontal direction, wherein the first access lines may be determined as one type of lines among (i) wordlines connected to each of gate terminals of each of the memory cells deployed in the vertical direction and (ii) bitlines connected to each of drain terminals of each of the memory cells deployed in the vertical direction; and second access lines, each of which is arranged in the second horizontal direction and each of which is deployed in the vertical direction, wherein the second access lines may be determined as a different type of lines among (i) wordlines connected to each of the gate terminals of each of the memory cells deployed in the second horizontal direction and (ii) bitlines connected to each of the drain terminals of each of the memory cells deployed in the second horizontal direction.

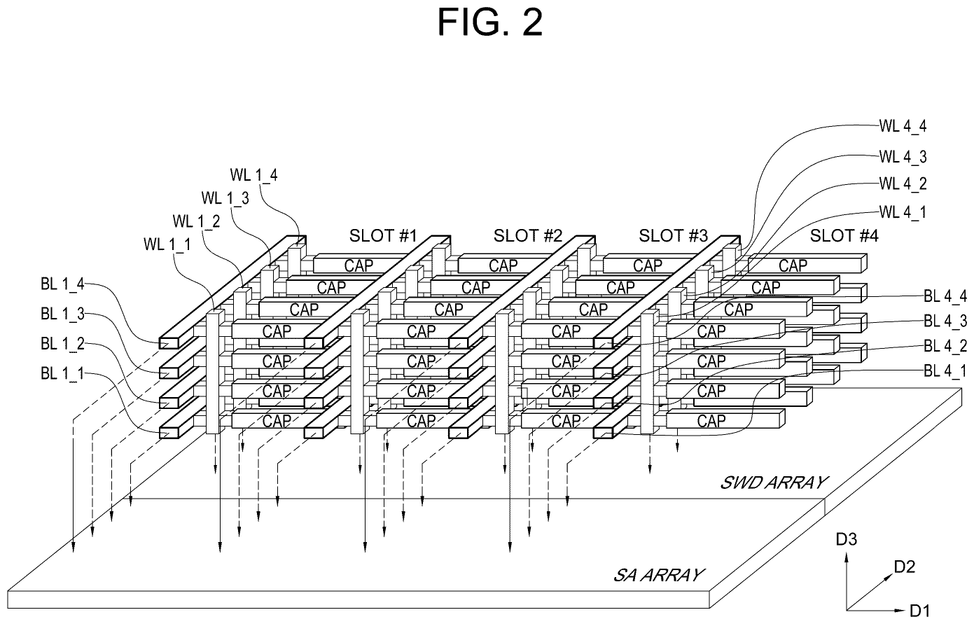

For example, FIG. 2 illustrates 4 memory cell slots with 4 memory cells deployed in the second horizontal direction and 4 memory cells deployed in the vertical direction, and illustrates the 3-dimensional memory device having the first memory cell slot Slot #1 to the fourth memory cell slot Slot #4 deployed in the first horizontal direction D1. That is, the first memory cell slot Slot #1 to the fourth memory cell slot Slot #4 may be repeatedly deployed in the first horizontal direction D1.

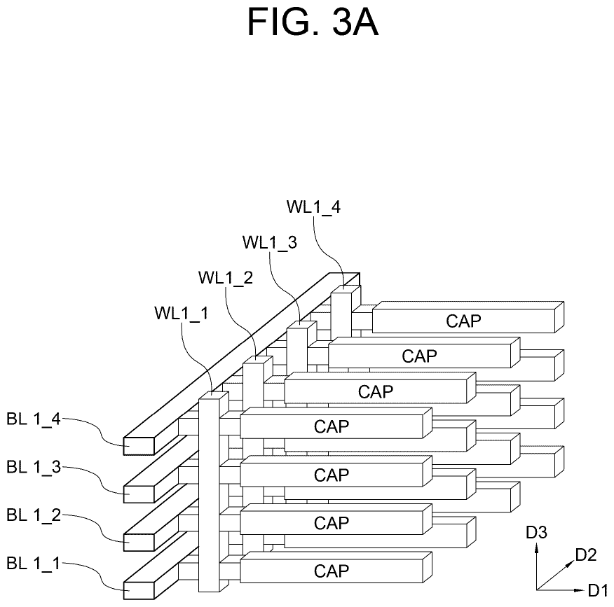

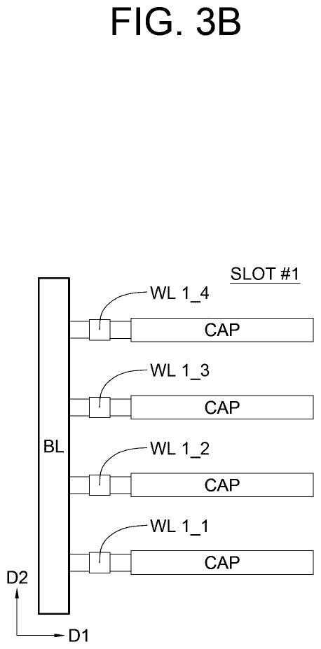

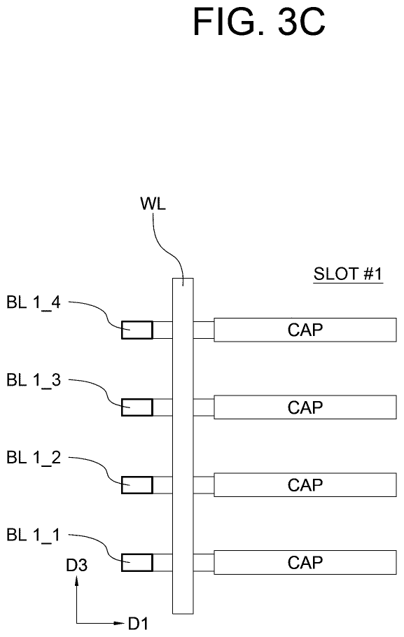

Herein, by referring to FIGS. 3A to 3C, it can be seen that the first memory cell slot Slot #1 has 4 memory cells deployed in the second horizontal direction D2 and 4 memory cells deployed in the vertical direction D3, each of which having 1 capacitor CAP and 1 transistor arranged in the first horizontal direction D1. That is, the 4 memory cells deployed in the second horizontal direction D2 are stacked 4 times in the vertical direction D3.

Further, the wordlines WL 1_1, WL 1_2, WL 1_3, and WL 1_4, which are the first access lines, may be arranged in the vertical direction D3, and each of the wordlines WL 1_1, WL 1_2, WL 1_3, and WL 1_4 may be connected to each of gate terminals of the 4 memory cells deployed in the vertical direction D3.

Furthermore, the bitlines BL 1_1, BL 1_2, BL 1_3, and BL 1_4, which are the second access lines, may be arranged in the second horizontal direction D2, and each of the bitlines BL 1_1, BL 1_2, BL 1_3, and BL 1_4 may be connected to each of drain terminals of the 4 memory cells deployed in the second horizontal direction D2.

Other memory cell slots may be formed in the same manner by using the above method. Through the above method, each of the 16 memory cells may be physically connected to one wordline and one bitline.

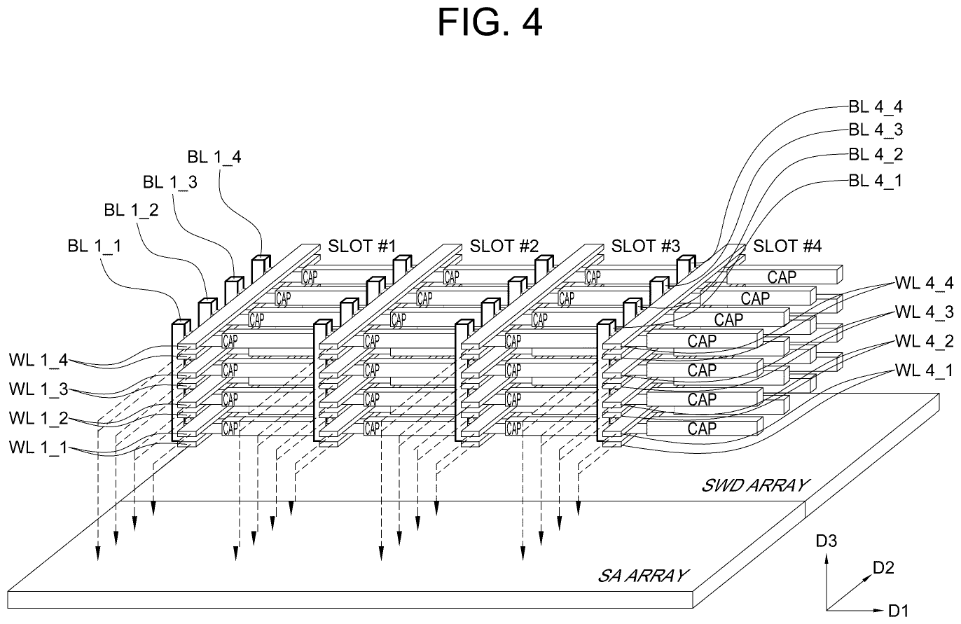

As another example, FIG. 4 illustrates 4 memory cell slots with 4 memory cells deployed in the second horizontal direction and 4 memory cells deployed in the vertical direction, and illustrates the 3-dimensional memory device having the first memory cell slot Slot #1 to the fourth memory cell slot Slot #4 deployed in the first horizontal direction D1. That is, each of the first memory cell slot Slot #1 to the fourth memory cell slot Slot #4 may be repeatedly deployed in the first horizontal direction D1.

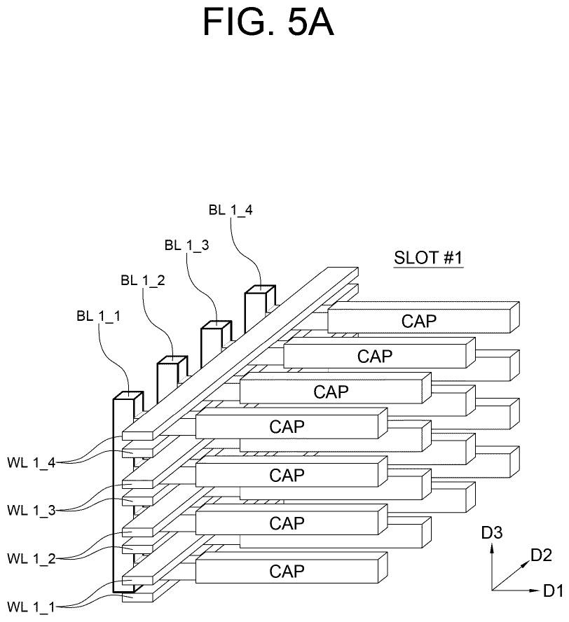

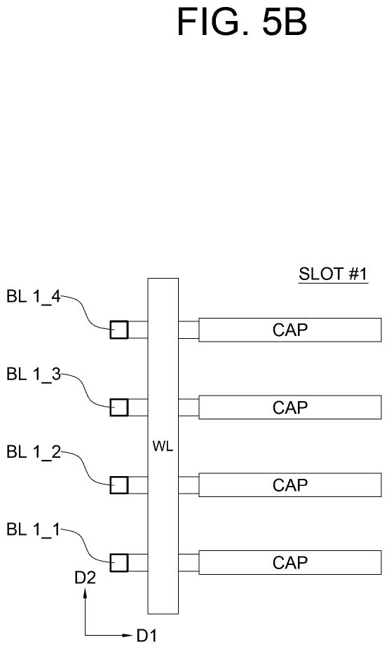

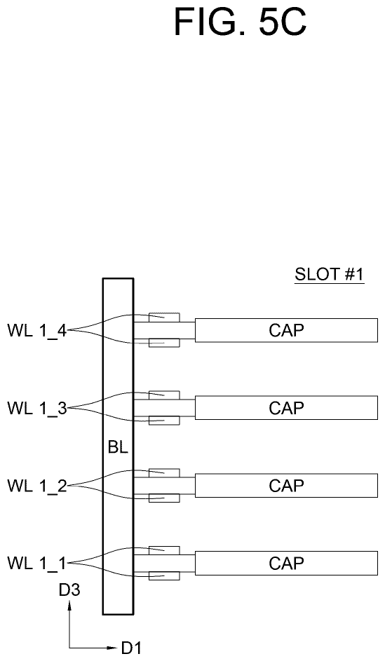

Herein, by referring to FIGS. 5A to 5C, it can be seen that the first memory cell slot Slot #1 has 4 memory cells deployed in the second horizontal direction D2 and 4 memory cells deployed in the vertical direction D3, each of which having 1 capacitor CAP and 1 transistor arranged in the first horizontal direction D1. That is, the 4 memory cells deployed in the second horizontal direction D2 may be stacked 4 times in the vertical direction D3.

Further, the bitlines BL 1_1, BL 1_2, BL 1_3, and BL 1_4, which are the first access lines, may be arranged in the vertical direction D3, and each of the bitlines BL 1_1, BL 1_2, BL 1_3, and BL 1_4 may be connected to each of drain terminals of the 4 memory cells deployed in the vertical direction D3.

Furthermore, the wordlines WL 1_1, WL 1_2, WL 1_3, and WL 1_4, which are the second access lines, may be arranged in the second horizontal direction D2, and each of the wordlines WL 1_1, WL 1_2, WL 1_3, and WL 1_4 may be connected to each of gate terminals of the 4 memory cells deployed in the second horizontal direction D2. Herein, as illustrated in FIG. 5C, each of the wordlines WL 1_1, WL 1_2, WL 1_3, and WL 1_4, may be formed with a split structure that surrounds an upper region and a lower region of a gate channel of a unit memory cell, or may be formed as a GAA (i.e., Gate-All-Around) structure that surrounds all regions of the gate channel.

Other memory cell slots may be formed in a same manner, and therefore, each of the 16 memory cells may be physically connected to one wordline and one bitline.

Next, by referring to FIGS. 2 and 4, the 3-dimensional memory device of the present disclosure may have at least two first access lines among the first access lines of the first memory cell slot to the first access lines of the n-th memory cell slot deployed at their corresponding same relative second horizontal directional positions that are connected to first global lines arranged in the first horizontal direction. Herein, “same relative . . . directional as in “their positions” corresponding same relative second horizontal directional positions” may refer to each of same relative positions in the second horizontal direction. That is, for the first access lines of the first memory cell slot to the first access lines of the n-th memory cell slot, one of the first access lines may be from a position (e.g., a third position in the second horizontal direction of the first access lines of the first memory cell slot), another one of the first access lines may be from a same relative position (e.g., a third position in the second horizontal direction of the first access lines of a second memory cell slot), etc. Therefore, they have the same relative positions (i.e., the third positions but of different memory cell slots). Herein, the first global lines may be connected to one type of circuit elements among each of sub-wordline drivers of a first circuit array and each of sense amplifiers of the first circuit array. Herein, the first circuit array may be positioned below the first memory cell slot to the n-th memory cell slot. Further, according to the 3-dimensional memory device of the present disclosure, the second access lines of the first memory cell slot to the second access lines of the n-th memory cell slot deployed at their corresponding same relative vertical directional positions may be (i) extended to a second circuit array positioned at an outer side region of the first memory cell slot to the n-th memory cell slot, and (ii) connected to a different type of circuit elements among each of the sub-wordline drivers of the second circuit array and each of the sense amplifiers of the second circuit array through vias deployed in the first horizontal direction. Herein, “same relative . . . directional positions” as in “their corresponding same relative vertical directional positions” may refer to each of same relative positions in the vertical direction. That is, for the second access lines of the first memory cell slot to the second access lines of the n-th memory cell slot, one of the second access lines may be from a position (e.g., a third position in the vertical direction of the second access lines of the first memory cell slot), another one of the second access lines may be from a same relative position (e.g., a third position in the vertical direction of the second access lines of the second memory cell slot), etc. Therefore, they have the same relative positions (i.e., the third positions in the vertical direction but of different memory cell slots). Herein, the second access lines of each of the memory cell slots extending to the second circuit array in order to connect to the different type of circuit elements through the vias are formed in a step shape. That is, each of extended portions of each of the second access lines that is connected to each of the vias in the second circuit array may be positioned in different vertical position from each other in the vertical direction D3.

Herein, the first access lines shared by the first global lines may be located in different memory cell slots so that a degree of integration can be improved without any issues in operating the 3-dimensional memory device. That is, in case wordlines from a same memory cell slot are being shared, activation signals are simultaneously applied to the plurality of wordlines corresponding to the same memory cell slot, therefore, reading or refreshing data may not be properly performed due to a plurality of cell voltages being charge-shared on one bitline. Further, in case bitlines of memory cells from the same memory cell slot are being shared, time delays may happen in a memory device when reading or refreshing data, because all memory cells connected to the shared bitlines corresponding to a wordline are being charge-shared, and reading or refreshing of data needs to be performed on other cells as well (i.e., cells that were affected by the charge-sharing effect) after reading or refreshing of data is performed on a target cell.

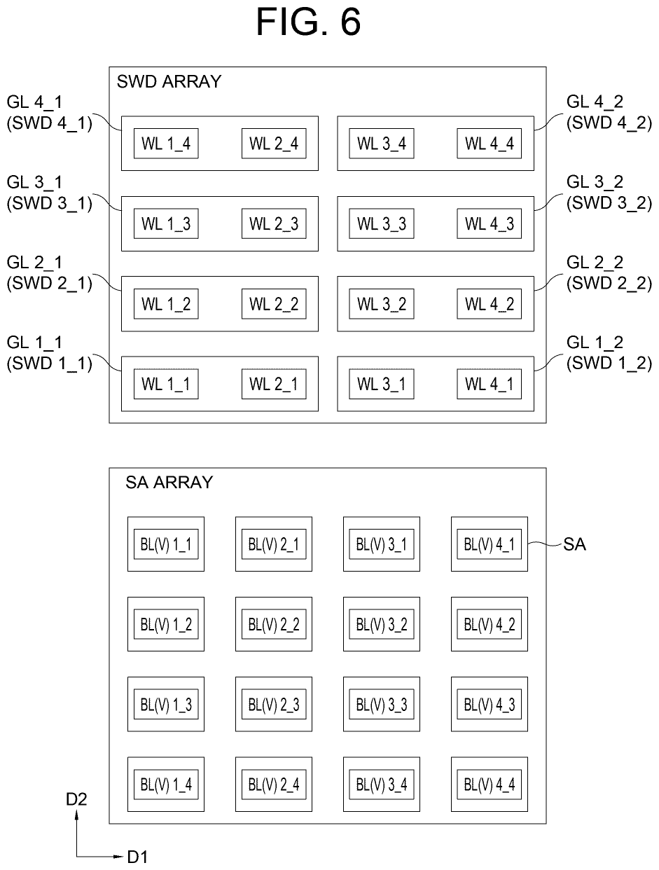

As one example, by referring to FIGS. 2 and 6, at least two wordlines among wordlines WL 1_* of the first memory cell slot Slot #1 to wordlines WL 4_* of the fourth memory cell slot Slot #4 deployed at their corresponding same relative second horizontal directional positions may each be connected to corresponding first global lines GL(s). Herein, the wordlines WL 1_* may be the first access lines of the first memory cell slot Slot #1 and the wordlines WL 4_* may be the first access lines of the fourth memory cell slot Slot #4 deployed at their corresponding same relative second horizontal directional positions. Herein, the first global lines GL(s) may be arranged in the first horizontal direction D1 and connected to each of sub-wordline drivers of a sub-wordline driver array SWD Array that is the first circuit array positioned below the first memory cell slot Slot #1 to the n-th memory cell slot Slot #4. Through this, a plurality of wordlines may be shared to one sub-wordline driver. Further, bitlines BL 1_* of the first memory cell slot Slot #1 to bitlines BL 4_* of the fourth memory cell slot Slot #4 deployed at their corresponding same relative vertical directional positions may be (i) extended to a sense amplifier array SA Array that is the second circuit array positioned at an outer side region of the first memory cell slot Slot #1 to the fourth memory cell slot Slot #4, and (ii) connected to sense amplifiers of the sense amplifier array SA Array through vias V(s) arranged in the first horizontal direction D1. Herein, the bitlines BL 1_* may be the second access lines of the first memory cell slot Slot #1 and the bitlines BL 4_* may be the second access lines of the fourth memory cell slot Slot #4 deployed at their corresponding same relative vertical directional positions.

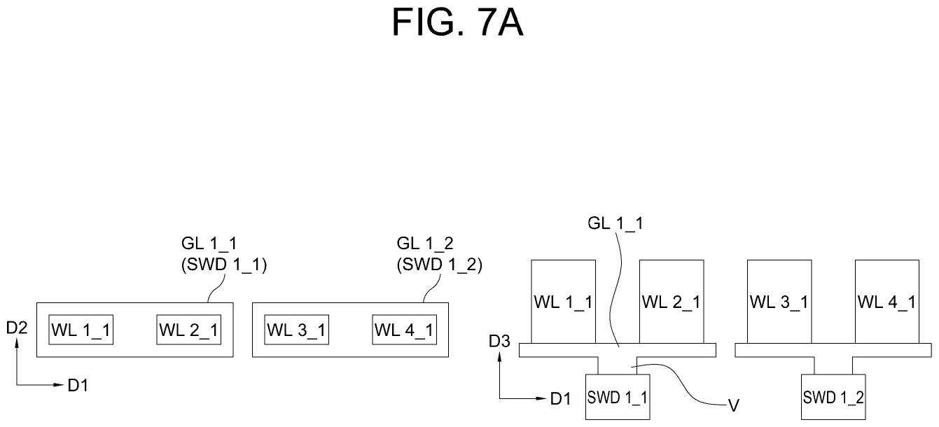

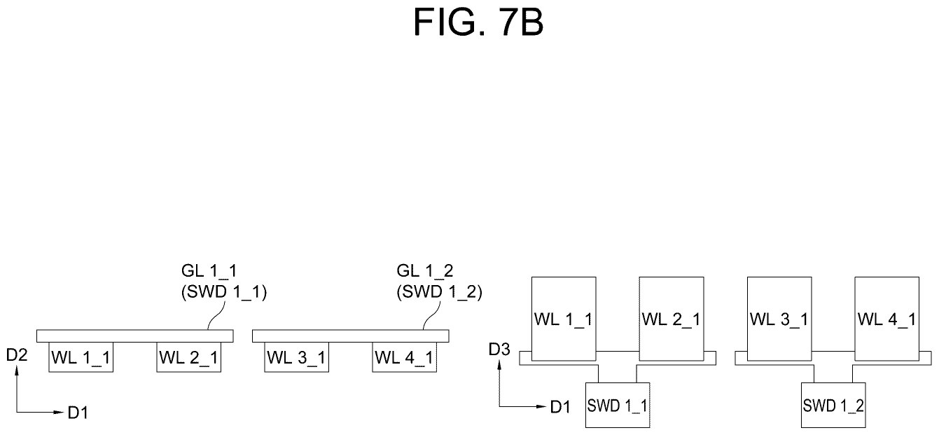

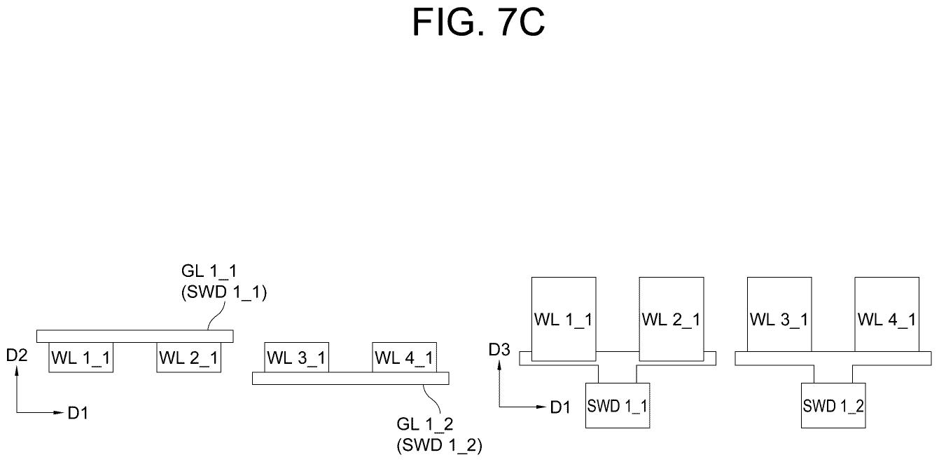

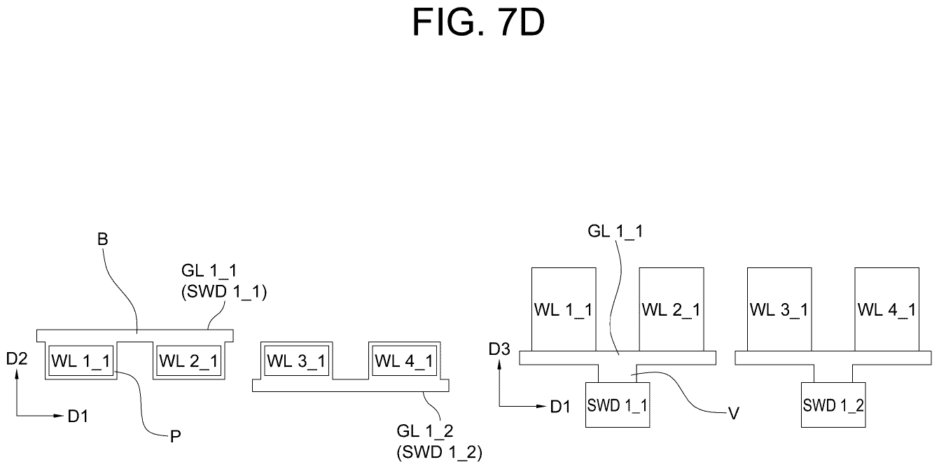

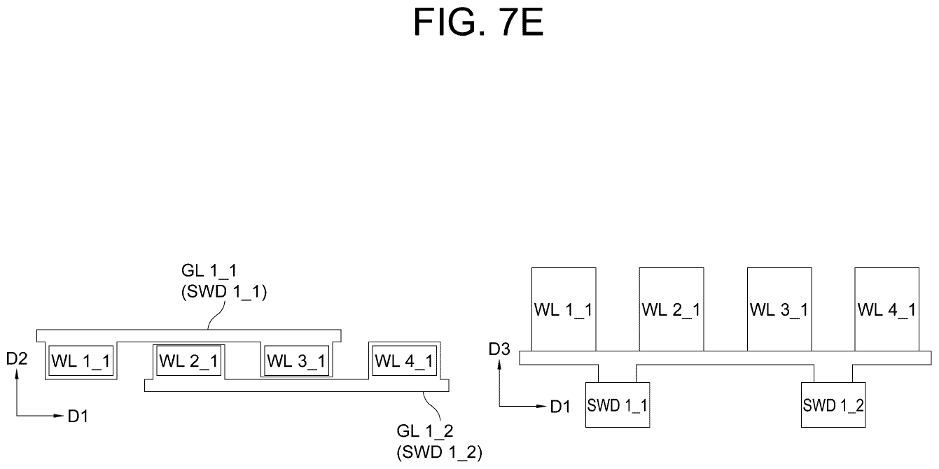

Herein, a structure of the first global lines that share the wordlines will be explained by referring to FIGS. 7A to 7E. It is to be noted that the structure of the first global lines of the present disclosure is not limited to structures described with reference to FIGS. 7A to 7E, but may be formed in various ways.

First, by referring to FIG. 7A, each of the first global lines GL(s) may share two or more adjacent wordlines WL(s). Further, each of the first global lines GL(s) may be formed at a lower region of two or more adjacent wordlines WL(s) that are being shared, and an upper region of each of the first global lines GL(s) may be connected to each of the wordlines WL(s) that are being shared. Herein, a lower region of each of the first global lines GL(s) may be connected to each of corresponding sub-wordline drivers SWD(s) through each of lower vias V(s). However, the present disclosure is not limited thereto, and a lower region of the global lines GL(s) may be directly connected to each of the sub-wordline drivers SWD(s).

Next, by referring to FIGS. 7B and 7C, it can be seen that each of the first global lines GL(s) may share two or more adjacent wordlines WL(s). Further, each of the first global lines GL(s) may be deployed in a side region of a first horizontal directional region of the sub-wordline driver array SWD Array, which is defined by two or more adjacent wordlines WL(s), and the corresponding two or more wordlines WL(s) may be connected to their corresponding side regions of the first global lines GL(s). Herein, a lower region of each of the first global lines GL(s) may be connected to each of corresponding sub-wordline drivers SWD(s) through each of lower vias. However, the present disclosure is not limited thereto, and the lower regions of the global lines GL(s) may be directly connected to each of corresponding sub-wordline drivers SWD(s). Furthermore, each of the first global lines GL(s) may be deployed in a side region of the first horizontal directional region, which is defined by two or more adjacent wordlines WL(s) deployed in the first horizontal direction D1, as illustrated in FIG. 7B, or may be alternately deployed at one side region and an opposite side region of the first horizontal directional region, which is defined by two or more adjacent wordlines WL(s) deployed in the first horizontal direction D1, as illustrated in FIG. 7C.

Next, by referring to FIG. 7D, it can be seen that each of the first global lines GL(s) may share two or more adjacent wordlines WL(s). Further, each of the first global lines GL(s) may include (i) first body lines B(s) deployed at a side region of a first horizontal directional region on the sub-wordline driver array, which is defined by two or more adjacent wordlines WL(s) deployed in the first horizontal direction D1, and (ii) first contact pads P(s) (ii-1) extended in the second horizontal direction D2 from each of the first body lines B(s), i.e., toward each of the wordlines WL(s) to be shared, and (ii-2) connected to each of the wordlines WL(s) to be shared. Herein, a lower region of each of the first global lines GL(s) may be connected to each of corresponding sub-wordline drivers SWD(s) through each of lower vias. However, the present disclosure is not limited thereto, and the lower region of each of the global lines GL(s) may be directly connected to each of corresponding sub-wordline drivers SWD(s). Furthermore, each of the first global lines GL(s) may be deployed in the side region of the first horizontal directional region, which is defined by two or more adjacent wordlines WL(s) deployed in the first horizontal direction D1, or may be alternately deployed at one side region and an opposite side region of the first horizontal directional region, which is defined by two or more adjacent wordlines WL(s) deployed in the first horizontal direction D1.

Next, by referring to FIG. 7E, it can be seen that each of the first global lines GL(s) may share two or more non-adjacent wordlines WL(s). Further, each of the first global lines GL(s) may include (i) first body lines deployed alternatively at one side and an opposite side of a first horizontal directional region, which is defined by two or more non-adjacent wordlines WL(s) deployed in the first horizontal direction D1, and (ii) first contact pads P(s) extended in the second horizontal direction D2 from each of the first body lines, i.e., toward each of the non-adjacent wordlines WL(s) to be shared, and connected to each of the non-adjacent wordlines WL(s) to be shared. Herein, a lower region of each of the first global lines GL(s) may be connected to each of corresponding sub-wordline drivers SWD(s) through each of lower vias. However, the present disclosure is not limited thereto, and the lower region of each of the global lines GL(s) may be directly connected to each of corresponding sub-wordline drivers SWD(s).

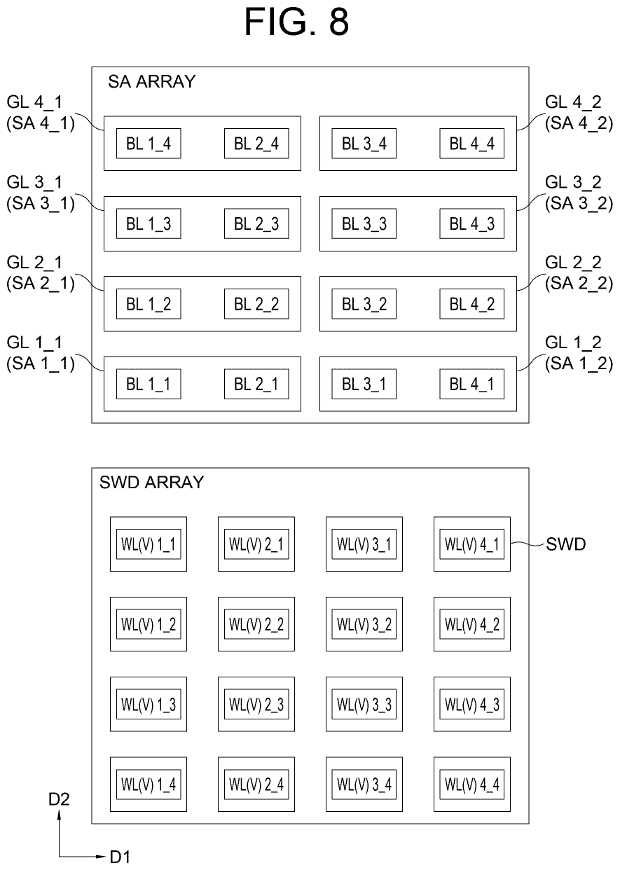

As another example, by referring to FIGS. 4 and 8, at least two bitlines among the bitlines BL 1_* of the first memory cell slot Slot #1 to the bitlines BL 4_* of the fourth memory cell slot Slot #4 deployed at their corresponding same relative second horizontal directional positions may each be connected to corresponding first global lines GL(s). Herein, the bitlines BL 1_* may be the first access lines of the first memory cell slot Slot #1 and the bitlines BL 4_* may be the first access lines of the fourth memory cell slot Slot #4 deployed at their corresponding same relative second horizontal directional positions. Herein, the first global lines GLs may be arranged in the first horizontal direction D1 and may be connected to each of sense amplifiers SA(s) of the sense amplifier array SA Array that is the first circuit array positioned below the first memory cell slot Slot #1 to the fourth memory cell slot Slot #4. Through this, a plurality of bitlines may be shared to one sense amplifier. Further, the wordlines WL 1_* of the first memory cell slot Slot #1 to the wordlines WL 4_* of the fourth memory cell slot Slot #4 deployed at their corresponding same relative vertical directional positions may be (i) extended to a sub-wordline driver array SWD Array that is the second circuit array positioned at the outer side region of the first memory cell slot Slot #1 to the fourth memory cell slot Slot #4, and (ii) connected to the sub-wordline drivers of the sub-wordline driver array SWD Array through vias V(s) arranged in the first horizontal direction D1. Herein, the wordlines WL 1_* may be the second access lines of the first memory cell slot Slot #1 and the wordlines WL 4_* may be the second access lines of the fourth memory cell slot Slot #4 deployed at their corresponding same relative vertical directional positions.

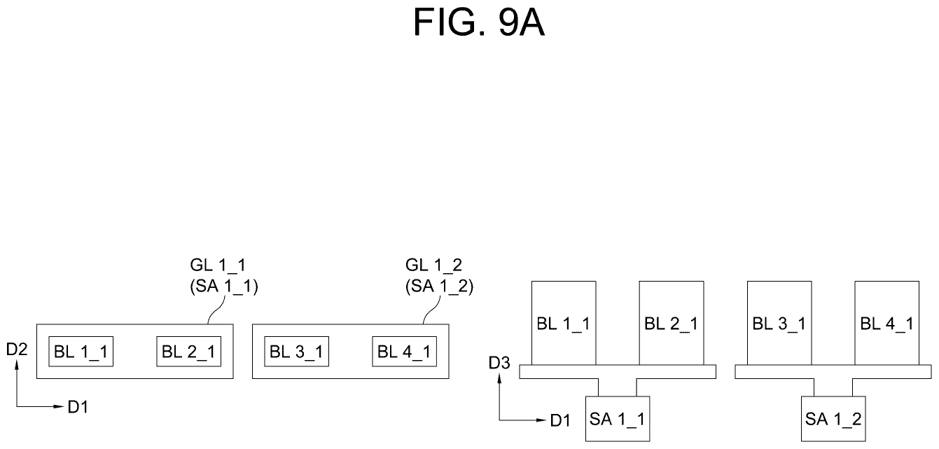

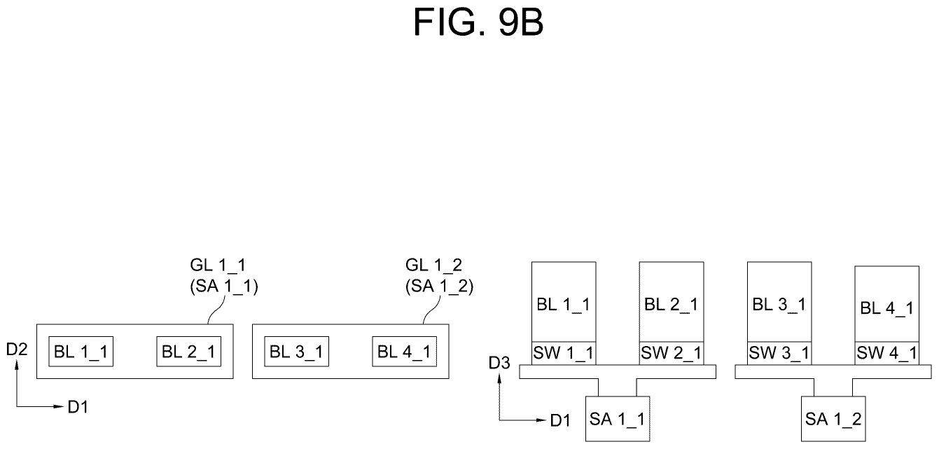

Herein, the structure of the first global lines that share the bitlines will be explained by referring to FIGS. 9A to 9B.

By referring to FIGS. 9A and 9B, each of the first global lines GL(s) may share two or more adjacent bitlines BL(s). Further, each of the first global lines GL(s) may be formed at a lower region of two or more adjacent bitlines BL(s) that are being shared, and an upper region of each of the first global lines GL(s) may be connected to each of the bitlines BL(s) that are being shared. Herein, a lower region of each of the first global lines GL(s) may be connected to each of corresponding sense amplifiers SA(s) through each of lower vias. However, the present disclosure is not limited thereto, and the lower region of each of the global lines GL(s) may be directly connected to each of corresponding sense amplifiers SA(s).

Further, the upper regions of each of the first global line GL(s) may be directly connected to each of the bitlines BL(s) that are being shared, as illustrated in FIG. 9A, or may be connected to each of the bitlines BL(s) that are being shared through switches SW(s), i.e., transistors, as illustrated in FIG. 9B. Herein, each of the switches SW(s) may be operated by signals of the wordlines corresponding the memory cells in order to read data written thereon.

However, the present disclosure is not limited thereto, and the first global lines may be of various structures like those previously described with reference to FIGS. 7B to 7E.

Meanwhile, in the above, structures of sharing the first access lines by using the first global lines were explained, and contrary to this, it is also possible to share the second access lines by using the second global lines.

That is, according to the 3-dimensional memory device of the present disclosure, the first access lines of the first memory cell slot to the first access lines of the n-th memory cell slot deployed at their corresponding same relative second horizontal directional positions may be connected to one type of circuit elements among each of sub-wordline drivers of the first circuit array and each of sense amplifiers of the first circuit array. Herein, the first circuit array may be positioned below the first memory cell slot to the n-th memory cell slot. Furthermore, according to the 3-dimensional memory device of the present disclosure, at least two second access lines among the second access lines of the first memory cell slot to the second access lines of the n-th memory cell slot deployed at their corresponding same relative vertical directional positions may be (i) extended to the second circuit array positioned at the outer side region of the first memory cell slot to the n-th memory cell slot, and (ii) connected to the second global lines arranged in the first horizontal direction through vias deployed in the first horizontal direction. Herein, the second global lines may be connected to a different type of circuit elements among each of the sub-wordline drivers of the second circuit array and each of the sense amplifiers of the second circuit array. Herein, in order to connect to each of the different type of circuit elements through the vias, the second access lines of a unit memory cell slot that are extended to the second circuit array may form a step shape. That is, each of extended portions of each of the second access lines that is connected to each of the vias in a region of the second circuit array may be deployed in different vertical position (i.e., level) from each other in the vertical direction D3.

Herein, the second access lines shared by the second global lines may be located in different memory cell slots so that a degree of integration can be improved without any issues in operating the 3-dimensional memory device. That is, in case the wordlines from a same memory cell slot are being shared, activation signals are simultaneously applied to the plurality of wordlines corresponding to the same memory cell slot, therefore, reading or refreshing data may not be properly performed due to a plurality of cell voltages being charge-shared on one bitline. Further, in case bitlines of memory cells from the same memory cell slot are being shared, time delays may happen in the memory device when reading or refreshing data, because all memory cells connected to the shared bitlines corresponding to a wordline are being charge-shared, and reading or refreshing of data needs to be performed on other cells as well (i.e., cells that were affected by the charge-sharing effect) after reading or refreshing of data is performed on a target cell.

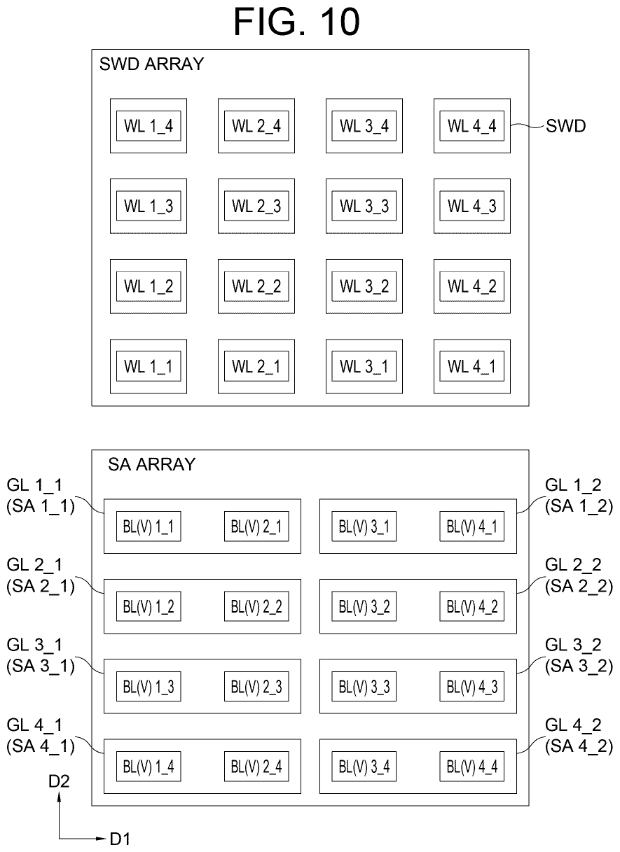

As one example, by referring to FIGS. 2 and 10, it can be seen that the wordlines WL 1_* of the first memory cell slot Slot #1 to the wordlines WL 4_* of the fourth memory cell slot Slot #4 deployed at their corresponding same relative second horizontal directional positions may be connected to each of the sub-wordline drivers of the sub-wordline driver array SWD Array that is the first circuit array positioned below the first memory cell slot Slot #1 to the fourth memory cell slot Slot #4. Herein, the wordlines WL 1_* may be the first access lines of the first memory cell slot Slot #1 and the wordlines WL 4_* may be the first access lines of the fourth memory cell slot Slot #4 deployed at their corresponding same relative second horizontal directional positions. Further, (i) the bitlines BL 1_* of the first memory cell slot Slot #1 to the bitlines BL 4_* of the fourth memory cell slot Slot #4 deployed at their corresponding same relative vertical directional positions may be extended to a sense amplifier array SA Array that is the second circuit array positioned at the outer side region of the first memory cell slot Slot #1 to the fourth memory cell slot Slot #4, and (ii) at least two bitlines among the bitlines BL 1_* of the first memory cell slot Slot #1 to the bitlines BL 4_* of the fourth memory cell slot Slot #4 may be connected to each of the second global lines GL(s) through vias deployed in the first horizontal direction D1. Herein, the bitlines BL 1_* may be the second access lines of the first memory cell slot Slot #1 and the bitlines BL 4_* may be the second access lines of the fourth memory cell slot Slot #4 deployed at their corresponding same relative vertical directional positions. Herein, the second global lines GL(s) may be arranged in the first horizontal direction D1 and may be connected to each of sense amplifiers of the sense amplifier array SA Array that is the second circuit array positioned at the outer side region of first memory cell slot Slot #1 to the fourth memory cell slot Slot #4. Through this, a plurality of bitlines may be shared to one sense amplifier.

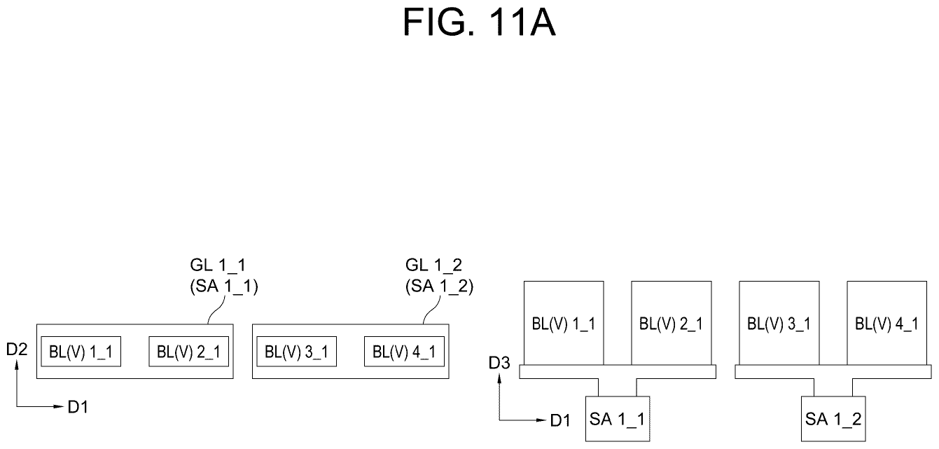

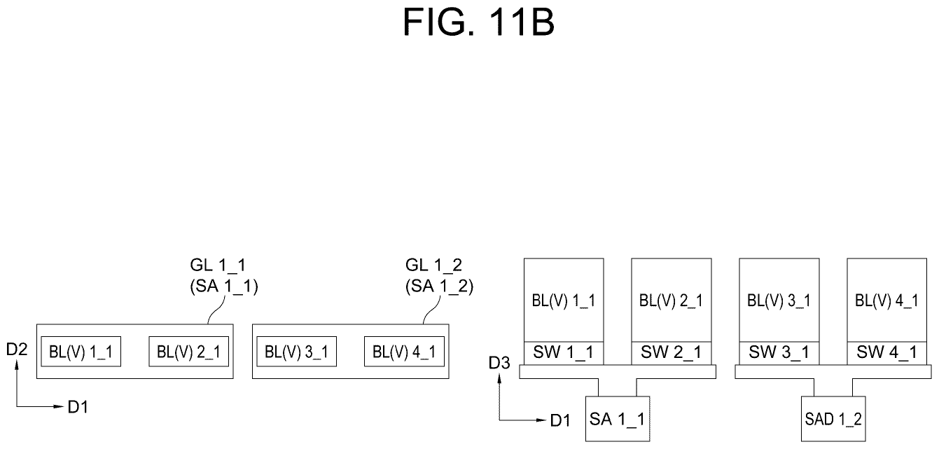

Herein, a structure of the second global lines that share the plurality bitlines will be explained by referring to FIGS. 11A to 11B.

By referring to FIGS. 11A and 11B, each of the second global lines GL(s) may share two or more adjacent bitlines BL(s). That is, each of the second global lines GL(s) may share two or more adjacent vias V(s) corresponding to two or more adjacent bitlines BL(s).

Further, each of the second global lines GL(s) may be formed at a lower region of the vias V(s) corresponding to two or more adjacent bitlines BL(s) that are being shared, and an upper region of each of the second global lines GL(s) may be connected to each of the vias V(s) corresponding to the bitlines BL(s) that are being shared. Herein, a lower region of each of the second global lines GL(s) may be directly connected to each of corresponding sense amplifiers SA(s) or may be connected to each of the sense amplifiers SA(s) through each of lower vias.

Meanwhile, an upper region of each of the second global lines GL(s) may be directly connected to the vias V(s) corresponding to each of the bitlines BL(s) that are being shared, as illustrated in FIG. 11A, or may be connected to the vias V(s) corresponding to each of the bitlines BL(s) that are being shared through switches SW(s), i.e., transistors, as illustrated in FIG. 11B.

However, the present disclosure is not limited thereto, and the second global lines may be of various structures like those of the first global lines that were previously described by referring to FIGS. 7B to 7E.

That is, each of the second global lines GL(s) may share the vias V(s) corresponding to two or more adjacent bitlines BL(s). Further, each of the second global lines GL(s) may be deployed in a side region of a first horizontal directional region of the sense amplifier array, which is defined by vias V(s) corresponding to two or more adjacent bitlines BL(s), and the vias V(s) corresponding to two or more bitlines BL(s) may be connected to side regions corresponding to the second global lines GL(s). Herein, a lower region of each of the second global lines GL(s) may be directly connected to each of corresponding sense amplifiers SA(s) or may be connected to each of corresponding sense amplifiers SA(s) through each of lower vias V(s). Furthermore, each of the second global lines GL(s) may be deployed at a side region of a first horizontal directional region, which is defined by the vias V(s) corresponding to two or more adjacent bitlines BL(s) deployed in the first horizontal direction D1, or may be alternately deployed at one side region and an opposite side region of a first horizontal directional region, which is defined by the vias V(s) corresponding to two or more adjacent bitlines BL(s) deployed in the first horizontal direction D1.

Additionally, each of the second global lines GL(s) may share the vias V(s) corresponding to two or more adjacent bitlines BL(s). Moreover, each of the second global lines GL(s) may include (i) second body lines B(s) deployed at a side region of a first horizontal directional region on the sense amplifier array, which is defined by the vias V(s) corresponding to two or more adjacent bitlines BL(s) deployed in the first horizontal direction D1, and (ii) second contact pads P(s) (ii-1) extended in the second horizontal direction D2 from each of the second body lines B(s), i.e., towards each of the vias V(s) corresponding to the bitlines BL(s) to be shared, and (ii-2) connected to each of the vias corresponding to the bitlines BL(s) to be shared. Herein, a lower region of each of the second global lines GL(s) may be directly connected to each of corresponding sense amplifiers SA(s) or connected to each of corresponding sense amplifiers SA(s) through each of lower vias. Further, each of the second global lines GL(s) may be deployed at a side of the first horizontal directional region, which is defined by the vias V(s) corresponding to two or more adjacent bitlines BL(s) deployed in the first horizontal direction D1, or may be alternately deployed at one side region and an opposite side region of the first horizontal directional region, which is defined by the vias V(s) corresponding to two or more adjacent bitlines BL(s) deployed in the first horizontal direction D1.

Additionally, each of the second global lines GL(s) may share the vias V(s) corresponding to two or more non-adjacent bitlines BL(s). Furthermore, each of the second global lines GL(s) may include (i) second body lines B(s) deployed alternatively at one side region and an opposite side region of a first horizontal directional region, which is defined by the vias V(s) corresponding to two or more non-adjacent bitlines BL(s) deployed in the first horizontal direction D1, and (ii) second contact pads P(s) (ii-1) extended in the second horizontal direction D2 from each of the second body lines B(s), i.e., towards each of the vias v(s) corresponding to the non-adjacent bitlines BL(s) to be shared, and (ii-2) connected to each of the vias corresponding to the non-adjacent bitlines BL(s) to be shared. Herein, a lower region of each of second global lines GL(s) may be directly connected to each of corresponding sense amplifiers SA(s) or may be connected to each of corresponding sense amplifiers SA(s) through each of lower vias.

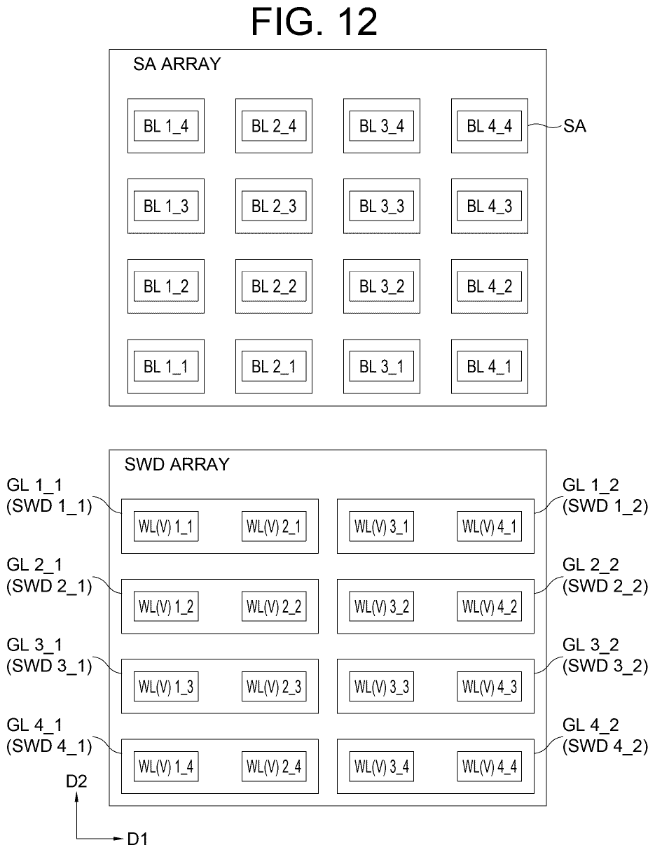

As another example, by referring to FIGS. 4 and 12, it can be seen that the bitlines BL 1_* of the first memory cell slot Slot #1 to the bitlines BL 4_* of the fourth memory cell slot Slot #4 deployed at their corresponding same relative second horizontal directional positions may be connected to each of the sense amplifiers SA(s) of the sense amplifier array SA Array that is the first circuit array positioned below of the first memory cell slot Slot #1 to the fourth memory cell slot Slot #4. Herein, the bitlines BL 1_* may be the first access lines of the first memory cell slot Slot #1 and the bitlines BL 4_* may be the first access lines of the fourth memory cell slot Slot #4 deployed at their corresponding same relative second horizontal directional positions. Further, (i) the wordlines WL 1_* of the first memory cell slot Slot #1 to the wordlines WL 4_* of the fourth memory cell slot Slot #4 deployed at their corresponding same relative vertical directional positions may be extended to the sub-wordline driver array SWD Array that is the second circuit array positioned at the outer side region of the first memory cell slot Slot #1 to the fourth memory cell slot Slot #4, and (ii) at least two wordlines among the wordlines WL 1_* of the first memory cell slot Slot #1 to the wordline WL 4_* of the fourth memory cell slot Slot #4 may be connected to each of the second global lines GL(s) through each of the vias V(s) deployed in the first horizontal direction D1. Herein, the wordlines WL 1_* may be the second access lines of the first memory cell slot Slot #1 and the wordlines WL 4_* may be the second access lines of the fourth memory cell slot Slot #4 deployed at their corresponding same relative vertical directional positions. Herein, the second global lines GL(s) may be arranged in the first horizontal direction D1 and connected to each of the sub-wordline drivers SWD(s) of the sub-wordline driver array SWD Array that is the second circuit array positioned at the outer side region of the first memory cell slot Slot #1 to the n-th memory cell slot Slot #4. Through this, a plurality of wordlines may be shared to one sub-wordline driver.

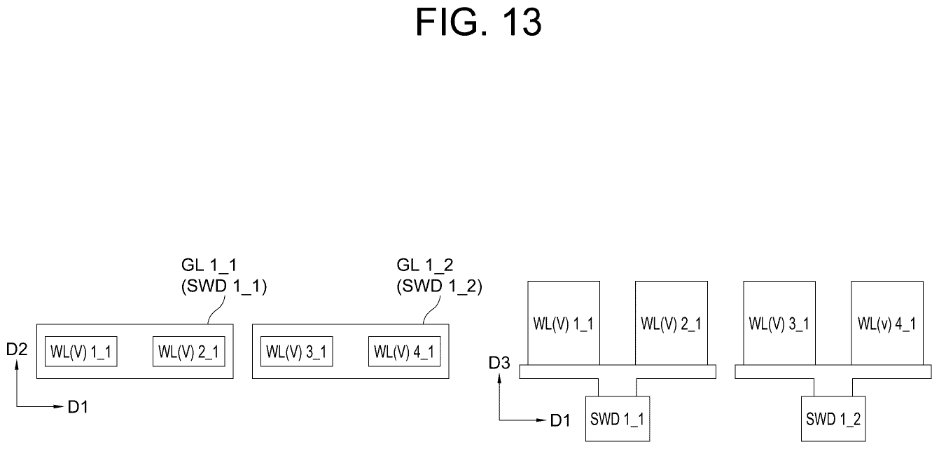

Herein, a structure of the second global lines that share the plurality wordlines will be explained by referring to FIG. 13.

By referring to FIG. 13, each of the second global lines GLs may share two or more adjacent wordlines WL(s). That is, each of the second global lines GL(s) may share two or more adjacent vias v(s) corresponding r more adjacent wordlines WL(s).

Further, each of the second global lines GL(s) may be formed at a lower region of the vias V(s) corresponding to two or more adjacent wordlines WL(s) that are being shared; and an upper region of each of the second global lines GL(s) may be connected to each of the vias V(s) corresponding to the wordlines WL(s) that are being shared. Herein, a lower region of each of the second global lines GL(s) may be directly connected to each of corresponding sub-wordline drivers SWD(s) or connected to each of the sub-wordline drivers SWD(s) through each of lower vias.

However, the present disclosure is not limited thereto, and the second global lines may be of various structures like those of the first global lines that were previously described with reference to FIGS. 7B to 7E.

That is, each of the second global lines GL(s) may share the vias V(s) corresponding to two or more adjacent wordlines WL(s). Further, each of the second global lines GL(s) may be deployed in a side region of a first horizontal directional region of the sub-wordline driver array, which is defined by vias V(s) corresponding to two or more adjacent wordlines WL(s), and the vias V(s) corresponding to two or more adjacent wordlines WL(s) may be connected to side regions corresponding to the second global lines GL(s). Herein, a lower region of each of the second global lines GL(s) may be directly connected to each of corresponding sub-wordline drivers SWD(s) or connected to each of corresponding sub-wordline drivers SWD(s) through each of lower vias. Furthermore, each of the second global lines GL(s) may be deployed at a side of the first horizontal directional region, which is defined by the vias V(s) corresponding to two or more adjacent wordlines WL(s) deployed in the first horizontal direction D1, or may be alternately deployed at one side region and an opposite side region of the first horizontal directional region, which is defined by the vias V(s) corresponding to two or more adjacent wordlines WL(s) deployed in the first horizontal direction D1.

Additionally, each of the second global lines GL(s) may share the vias V(s) corresponding to two or more adjacent wordlines WL(s). Moreover, each of the second global lines GL(s) may include (i) second body lines B(s) deployed at a side region of a first horizontal directional region on the sub-wordline driver array SWD Array, which is defined by the vias V(s) corresponding to two or more adjacent wordlines WL(s) deployed in the first horizontal direction D1, and (ii) second contact pads P(s) (ii-1) extended in the second horizontal direction D2 from each of the second body lines B(s), i.e., towards each of the vias V(s) corresponding to the wordlines WL(s) to be shared, and (ii-2) connected to each of the vias corresponding to the wordlines WL(s) to be shared. Herein, a lower region of each of the second global lines GL(s) may be directly connected to each of corresponding sub-wordline drivers SWD(s) or connected to each of corresponding sub-wordline drivers SWD(s) through each of lower vias. Further, each of the second global lines GL(s) may be deployed at a side of the first horizontal directional region, which is defined by the vias V(s) corresponding to two or more adjacent wordlines WL(s) deployed in the first horizontal direction D1, or may be alternately deployed at one side region and an opposite side region of the first horizontal directional region, which is defined by the vias V(s) corresponding to two or more adjacent wordlines WL(s) deployed in the first horizontal direction D1.

Additionally, each of the second global lines GL(s) may share the vias V(s) corresponding to two or more non-adjacent wordlines WL(s). Furthermore, each of the second global lines GL(s) may include (i) second body lines B(s) deployed alternatively at one side region and an opposite side region of the first horizontal directional region, which is defined by the vias V(s) corresponding to two or more non-adjacent wordlines WL(s) deployed in the first horizontal direction D1, and (ii) second contact pads P(s) (ii-1) extended in the second horizontal direction D2 from each of the second body lines B(s), i.e., towards each of the vias v(s) corresponding to the non-adjacent wordlines WL(s) to be shared, and (ii-2) connected to each of the vias corresponding to the non-adjacent wordlines WL(s) to be shared. Herein, a lower region of each of the second global lines GL(s) may be directly connected to each of corresponding sub-wordline drivers SWD(s) or connected to each of corresponding sub-wordline drivers SWD(s) through each of lower vias.

### Second Example Embodiment

The second example embodiment of the present disclosure is different from the first example embodiment in which either the first access lines are being shared or the second access lines are being shared. In the second example embodiment, the first access lines and the second access lines may be simultaneously shared. Therefore, similar explanations that are deducible from the above first example embodiment will be omitted.

According to a 3-dimensional memory device of the present disclosure, it may include a first memory cell slot to an n-th memory cell slot deployed in the first horizontal direction, as illustrated in FIG. 2 to FIG. 5C. Herein, n may be an integer greater than or equal to 2. That is, each of the first memory cell slot to the n-th memory cell slot may include: memory cells deployed in a second horizontal direction orthogonal to the first horizontal direction and deployed in a vertical direction; first access lines deployed in the second horizontal direction and arranged in the vertical direction, wherein the first access lines may be determined as one type of lines among (i) wordlines connected to each of gate terminals of each of the memory cells deployed in the vertical direction and (ii) bitlines connected to each of drain terminals of each of the memory cells deployed in the vertical direction; and second access lines deployed in the vertical direction and arranged in the second horizontal direction, wherein the second access lines may be determined as a different type of lines among (i) wordlines connected to each of the gate terminals of each of the memory cells deployed in the second horizontal direction and (ii) bitlines connected to each of the drain terminals of each of the memory cells deployed in the second horizontal direction.

Next, a structure that allows the first access lines to be shared and allow the second access lines to be shared simultaneously will be explained below. That is, the 3-dimensional memory device of the present disclosure may have at least two first access lines among the first access lines of the first memory cell slot to the first access lines of the n-th memory cell slot deployed at their corresponding same relative second horizontal directional positions to be connected to first global lines arranged in the first horizontal direction. Herein, the first global lines may be connected to one type of circuit elements among each of sub-wordline drivers of a first circuit array and each of sense amplifiers of the first circuit array. Herein, the first circuit array may be positioned below the first memory cell slot to the n-th memory cell slot. Further, according to the 3-dimensional memory device of the present disclosure, at least two second access lines among the second access lines of the first memory cell slot to the second access lines of the n-th memory cell slot deployed at their corresponding same relative vertical directional positions may be extended to a second circuit array positioned at an outer side region of the first memory cell slot to the n-th memory cell slot; and at least two second access lines among the second access lines of the first memory cell slot to the second access slot deployed at their lines of the n-th memory cell corresponding same relative vertical directional positions may be (i) connected to a different type of circuit elements among each of the sub-wordline drivers of the second circuit array and each of the sense amplifiers of the second circuit array, and (ii) connected to the second global lines arranged in the first horizontal direction through the vias deployed in the first horizontal direction.

As one example, in case the first access lines that are deployed at a corresponding specific same relative second horizontal directional position, among the first access lines of the first memory cell slot to the first access lines of the n-th memory cell slot deployed at their corresponding same relative second horizontal directional positions, are defined as a (1_1)-st access line to a (1_n)-th access line, each of the first global lines may share m first access lines, which are sequentially adjacent access lines, among the (1_1)-st access line to the (1_n)-th access line. Herein, m may be an integer greater than or equal to 2. Further, in case the second access lines that are deployed at a corresponding specific same relative vertical directional position, among the second access lines of the first memory cell slot to the second access lines of the n-th memory cell slot deployed at their corresponding relative same vertical directional positions, are defined as a (2_1)-st access line to a (2_n)-th access line, each of the second global lines may share n/m second access lines, which are sequentially m-th adjacent access lines, among the (2_1)-st access line to the (2_n)-th access line.

Herein, each of the first global lines may be formed at a lower region of the m first access lines that are sequentially adjacent, among the (1_1)-st access line to the (1_n)-th access line, and may be connected to each of the m first access lines that are sequentially adjacent. Further, each of the second global lines may include second body lines formed at a lower side region of a first horizontal directional region, which is defined by a first via to an n-th via corresponding to the (2_1)-st access line to the (2_n)-th access line, and second contact pads extending in the second horizontal direction from each of the second body lines, wherein the second contact pads are connected to n/m vias, which are sequentially m-th adjacent vias, among the first via to the n-th via.

Furthermore, in case the first access lines are the bitlines, each of the first global lines may be formed at a lower region of the m first access lines that are sequentially adjacent, among the (1_1)-st access line to the (1_n)-th access line, and may be connected directly or connected through switches to each of the m first access lines that are sequentially adjacent. Moreover, in case the second access lines are the bitlines, each of the second global lines may be connected directly or connected through switches to each of the n/m vias, which are sequentially m-th adjacent vias, among the first via to the n-th via.

Further, each of the second body lines corresponding to each of the second global lines may be alternatively arranged at one side and an opposite side of a first horizontal directional region, which is defined by the first via to the n-th via.

Meanwhile, among n first access lines, where n is the number of the first access lines of the first memory cell slot to the first access lines of the n-th memory cell slot that are deployed at their same relative second horizontal directional positions, there may be a difference in a sharing method of the first access lines and the second access lines depending on sequentially adjacent m first access lines shared by each of the first global lines.

That is, when n, which is the number of the first access lines that are deployed at their same relative horizontal directional positions, is a multiple of m, which is the number of the n first access lines being shared, the first global lines may include a (1_1)-st global line to a (1 (n/m))-th global line, and a (1_j)-th global line may share a (1_(1+(j−1)*m))-th access line to a (1_j*m)-th access line. Herein, j may be an integer greater than or equal to 1 and less than or equal to n/m. Further, the second global lines may include a (2_1)-st global line to a (2_m)-th global line, and a (2_k)-th global line may share a (2_(k+(s−1)*m))-th access line. Herein, k may be an integer greater than or equal to 1 and less than or equal to m, and s may be integers greater than or equal to 1 and less than or equal to n/m.

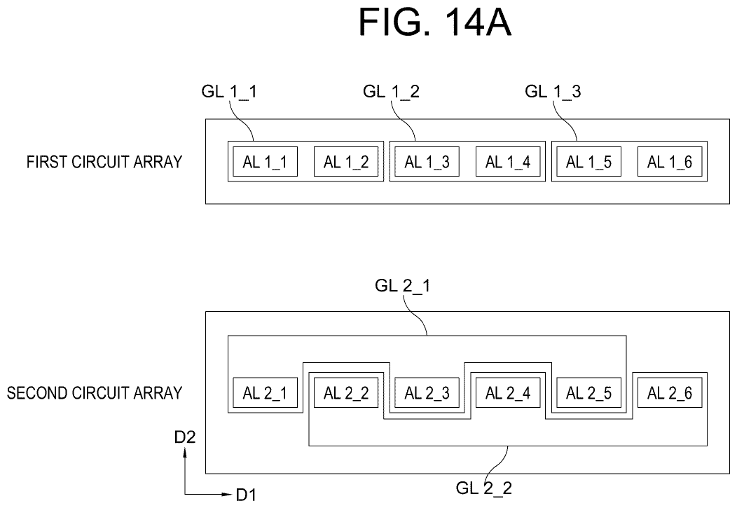

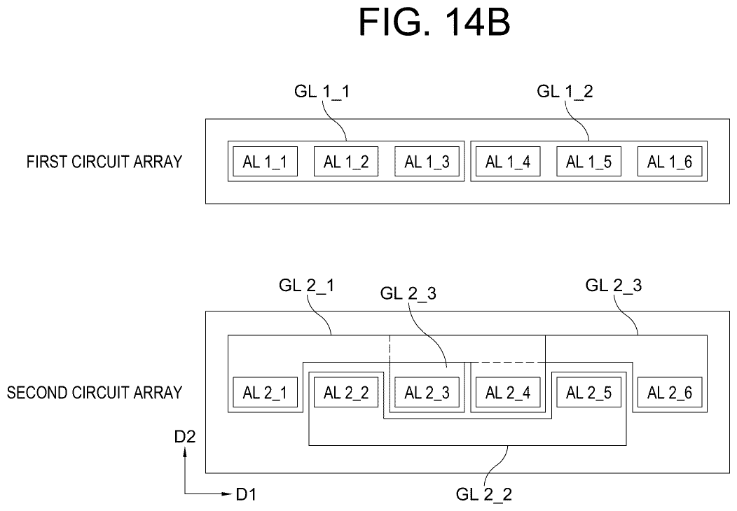

FIG. 14A illustrates one example of sharing 2 first access lines among 6 first access lines, which are the (1_1)-st access line to the (1_6)-th access line of the first circuit array in 6 memory cell slots, that is, when n is 6.

First, since n/m is 3, 2 adjacent first access lines may be shared by using 3 first global lines. That is, in the first circuit array, a (1_1)-st global line GL 1_1 may share a (1_1)-st access line AL 1_1 and a (1_2)-nd access line AL 1_2, a (1_2)-nd global line GL 1_2 may share a (1_3)-rd access line AL 1_3 and a (1_4)-th access line AL 1_4, and a (1_3)-rd global line GL 1_3 may share a (1_5)-th access line AL 1_5 and a (1_6)-th access line AL 1_6.

Next, since m is 2, 3 second access lines that are sequentially 2-nd adjacent second access lines may be shared by using 2 second global lines. That is, in the second circuit array, (i) a (2_1)-st global line GL 2_1 may share a (2_1)-st access line AL 2_1, a (2_3)-rd access line AL 2_3, and a (2_5)-th access line AL 2_5, and (ii) a (2_2)-nd global line GL 2_2 may share a (2_2)-nd access line AL 2_2, a (2_4)-th access line AL 2_4, and a (2_6)-th access line AL 2_6.

FIG. 14B illustrates another example of sharing 3 first access lines among 6 first access lines, which are the (1_1)-st access line to the (1_6)-th access line of the first circuit array in the 6 memory cell slots, that is, when n is 6.

First, since n/m is 2, 3 adjacent first access lines may be shared by using 2 first global lines. That is, in the first circuit array, (i) the (1_1)-st global line GL 1_1 may share the (1_1)-st access line AL 1_1, the (1_2)-nd access line AL 1_2, and the (1_3)-rd access line AL 1_3, and (ii) the (1_2)-nd global line GL 1_2 may share the (1_4)-th access line AL 1_4, the (1_5)-th access line AL 1_5, and the (1_6)-th access line AL 1_6.

Next, since m is 3, 2 second access lines that are sequentially 3-rd adjacent second access lines may be shared by using 3 second global lines. That is, in the second circuit array, the (2_1)-st global line GL 2_1 may share the (2_1)-st access line AL 2_1 and the (2_4)-th access line AL 2_4, the (2_2)-nd global line GL 2_2 may share the (2_2)-nd access line AL 2_2 and the (2_5)-th access line AL 2_5, and the (2_3)-rd global line GL 2_3 may share the (2_3)-rd access line AL 2_3 and the (2_6)-th access line AL 2_6. Herein, the (2_1)-st global line GL 2_1 and the (2_3)-rd global line GL 2_3 may be on different levels, that is, deployed on different levels in the vertical direction.

Meanwhile, contrary to above, when n, which is the number of the first access lines that are deployed at their same relative horizontal directional positions, is not a multiple of m, which is the number of the n first access lines being shared, the first global lines may include a (1_1)-st global line to a (1_[n/m])-th global line, and a (1_j)-th global line may share a (1_(1+(j−1)*m))-th access line to a (1_j*m)-th access line. Herein, [n/m] may be a Gaussian function representing a maximum integer not greater than n/m, and j may be an integer greater than or equal to 1 and less than or equal to [n/m]. Further, the second global lines may include the (2_1)-st global line to the (2 m)-th global line, and a (2_k)-th global line shares a (2_(k+(s−1)*m))-th access line. Herein, k may be an integer greater than or equal to 1 and less than or equal to m, and s may be integers greater than or equal to 1 and less than or equal to [n/m].

Additionally, (i) a (1_(m*[n/m]+1))-th access line to the (1_n)-th access line, which exclude the (1_1)-st access line to a (1_(m*[n/m]))-th access line among the (1_1)-st access line to the (1_n)-th access line, wherein the (1_1)-st access line to the (1_(m*[n/m]))-th access line are being shared, and (ii) a (2_(m*[n/m]+1))-th access line to the (2_n)-th access line, which exclude the (2_1)-st access line to a (2_(m*[n/m]))-th access line among the (2_1)-st access line to the (2_n)-th access line, wherein the (2_1)-st access line to the (2_(m*[n/m]))-th access line are being shared, may be shared by using m′, which is different from m. Contrary to above, the (1_(m*[n/m]+1))-th access line to the (1_n)-th access line and the (2_(m*[n/m]+1))-th access line to the (2_n)-th access line may not be shared.

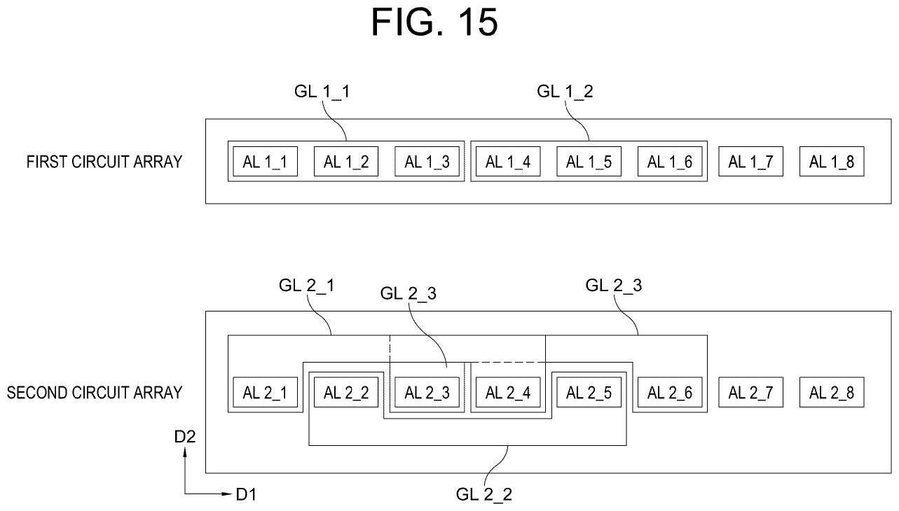

FIG. 15 illustrates one example of sharing 3 first access lines among 8 first access lines, which are the (1_1)-st access line to the (1_8)-th access line of the first circuit array in 8 memory cell slots, that is, when n is 8.

First, considering that [n/m] is 2, since n/m, which is 8/3, is not an integer, 3 adjacent first access lines may be shared by using 2 first global lines. That is, in the first circuit array, (i) the (1_1)-st global line GL 1_1 may share the (1_1)-st access line AL 1_1, the (1_2)-nd access line AL 1_2, and the (1_3)-rd access line AL 1_3, and (ii) the (1_2)-nd global line GL 1_2 may share the (1_4)-th access line AL 1_4, the (1_5)-th access line AL 1_5, and the (1_6)-th access line AL 1_6.

Next, since m is 3, 2 second access lines that are sequentially 3-rd adjacent second access lines may be shared by using 3 second global lines. That is, in the second circuit array, the (2_1)-st global line GL 2_1 may share the (2_1)-st access line AL 2_1 and the (2_4)-th access line AL 2_4, the (2_2)-nd global line GL 2_2 may share the (2_2)-nd access line AL 2_2 and the (2_5)-th access line AL 2_5, and the (2_3)-rd global line GL 2_3 may share the (2_3)-rd access line AL 2_3 and the (2_6)-th access line AL 2_6. Herein, the (2_1)-st global line GL 2_1 and the (2_3)-rd global line GL 2_3 may be on different levels, that is, deployed on different levels in the vertical direction.

Accordingly, the (1_1)-st access line to the (1_6)-th access line of the first circuit array may be shared, and the (2_1)-st access line to the (2_6)-th access line of the second circuit array may be shared.

Further, a (1_7)-th access line AL 1_7 and a (1_8)-th access line AL 1_8 of the first circuit array, and a (2_7)-th access line AL 2_7 and a (2_8)-th AL 2_8 of the second circuit array may not be shared.

Therefore, the (1_7)-th access line AL 1_7 and the (1_8)-th access line AL 1_8 of the first circuit array, and the (2_7)-th access line AL 2_7 and the (2_8)-th AL 2_8 of the second circuit array may be additionally shared by using m′, which may be an integer smaller than m (i.e., 3 in this example).

Herein, in FIG. 15, 2 first access lines and 2 second access lines are still remaining, therefore, like the first example embodiment of the present disclosure, only the remaining 2 first access lines may be shared, or only the remaining 2 second access lines may be shared.

That is, according to the present disclosure, processes of sharing an initial m first access lines and processes of sharing remaining first access lines that have not been yet shared by using m′ that is smaller than m may be repeated.

Meanwhile, in the above, the (1_7)-th access line AL 1_7 and the (1_8)-th access line AL 1_8 of the first circuit array, and the (2_7)-th access line AL 2_7 and the (2_8)-th access line AL 2_8 of the second circuit array are additionally being shared, but, contrary to this, the (1_7)-th access line AL 1_7 and the (1_8)-th access line AL 1_8 of the first circuit array and the (2_7)-th access line AL 2_7 and the (2_8)th access line AL 2_8 of the second circuit array may remain as not being shared.

According to the present disclosure, the degree of integration of the 3-dimensional memory device may improve without problems by forming wordline groups to share the wordlines and sharing bitlines corresponding to wordlines of different wordline groups.

Meanwhile, in the above, the first global lines may share adjacent first access lines, and the second global lines may share non-adjacent second access lines, however, different from above, the second global lines may share adjacent second access lines, and the first global lines may share non-adjacent first access lines.

That is, in case the second access lines that are deployed at a corresponding specific same relative vertical directional position, among the second access lines of the first memory cell slot to the second access lines of the n-th memory cell slot deployed at their corresponding relative same vertical directional positions, are defined as the (2_1)-st access line to the (2_n)-th access line, each of the second global lines may share m second access lines, which are sequentially adjacent access lines, among the (2_1)-st access line to the (2_n)-th access line. Further, in case the first access lines that are deployed at a corresponding specific same relative second horizontal directional position, among the first access lines of the first memory cell slot to the first access lines of the n-th memory cell slot deployed at their corresponding same relative second horizontal directional positions, are defined as a (1_1)-st access line to a (1_n)-th access line, each of the first global lines may share n/m first access lines, which are sequentially m-th adjacent access lines, among the (1_1)-st access line to the (1_n)-th access line.

Herein, each of the second global lines may be formed at a lower region of m vias that are sequentially adjacent, among a first via to an n-th via corresponding to the (2_1)-st access line to the (2_n)-th access line, and connected to each of the m vias that are sequentially adjacent. Further, each of the first global lines may include first body lines formed at a lower side region of a first horizontal directional region, which is defined by the (1_1)-st access line to the (1_n)-th access line, and first contact pads extending in the second horizontal direction from each of the first body lines. Herein, the first contact pads may be connected to the n/m first access lines, which are sequentially m-th adjacent access lines, among the (1_1)-st access line to the (1_n)-th access line.

Furthermore, in case the second access lines are the bitlines, each of the second global lines may be formed at a lower region of the m vias that are sequentially adjacent, among the first via to the n-th via, and may be connected directly or connected through switches to each of the m vias that are sequentially adjacent. Moreover, in case the first access lines are the bitlines, each of the first global lines may be connected directly or connected through switches to each of the n/m first access lines, which are sequentially m-th adjacent access lines, among the (1_1)-st access line to the (1_n)-th access line.

Additionally, each of the first body lines corresponding to each of the first global lines may be alternatively arranged at one side and an opposite side of the first horizontal directional region, which is defined by the (1_1)-st access line to the (1_n)-th access line.

Meanwhile, among n second access lines, where n is the number of the second access lines of the first memory cell slot to the second access lines of the n-th memory cell slot that are deployed at their same relative vertical directional positions, there may be a difference in a sharing method of the first access lines and the second access lines depending on sequentially adjacent m second access lines shared by each of the second global lines.

That is, in case n is a multiple of m, the second global lines may include a (2_1)-st global line to a (2_(n/m))-th global line, and a (2_j)-th global line shares a (2 (1+(j−1)*m))-th access line to a (2_j*m)-th access line. Further, the first global lines may include a (1_1)-st global line to a (1_m)-th global line, and a (1_k)-th global line may share a (1_(k+(s−1)*m))-th access line.

Furthermore, in case n is not a multiple of m, the second global lines may include a (2_1)-st global line to a (2 [n/m])-th global line and a (2_j)-th global line may share a (1_(1+(j−1)*m))-th access line to a (1_j*m)-th access line. Moreover, the first global lines may include a (1_1)-st global line to a (1_m)-th global line, and a (1_k)-th global line may share a (1_(k+(s−1)*m))-th access line.

Additionally, (i) a (2_(m*[n/m]+1))-th access line to the (2_n)-th access line, which exclude the (2_1)-st access line to a (2_(m*[n/m]))-th access line among the (2_1)-st access line to the (2_n)-th access line, wherein the (2_1)-st access line to the (2_(m*[n/m]))-th access line are being shared, and (ii) a (1_(m*[n/m]+1))-th access line to the (1_n)-th access line, which exclude the (1_1)-st access line to a (1_(m*[n/m]))-th access line among the (1_1)-st access line to the (1_n)-th access line, wherein the (1_1)-st access line to the (1_(m*[n/m]))-th access line are being shared, may be shared by using m′, which is different from m. Contrary to the above, the (2_(m*[n/m]+1))-th access line to the (2_n)-th access line and the (1_(m*[n/m]+1))-th access line to the (1_n)-th access line may not be shared.

Since this can be easily understood from the previous explanation by referring to FIGS. 14A to 15, detailed descriptions thereof will be omitted.

The present disclosure has an effect of providing the 3-dimensional memory device with an increased degree of integration.

The present disclosure has another effect of providing the 3-dimensional memory device with the increased degree of integration by reducing a sum of area of the sub-wordline driver array and the sense amplifier array.

The present disclosure has still another effect of providing the 3-dimensional memory device with a reduced area of the sub-wordline driver array and/or the sense amplifier array by allowing one of sub-wordline drivers and/or one of the sense amplifiers to share a plurality of bitlines and/or a plurality of wordlines.

The present disclosure has still yet another effect of providing the 3-dimensional memory device that shares the bitlines through the sense amplifier without time delays in a read operation.

As seen above, the present disclosure has been explained by specific matters such as detailed components, limited embodiments, and drawings. They have been provided only to help more general understanding of the present disclosure. It, however, will be understood by those skilled in the art that various changes and modification may be made from the description without departing from the spirit and scope of the disclosure as defined in the following claims.

Accordingly, the thought of the present disclosure must not be confined to the explained embodiments, and the following patent claims as well as everything including variations equal or equivalent to the patent claims pertain to the category of the thought of the present disclosure.

What is claimed is:

1. A 3-dimensional memory device, comprising:
a first memory cell slot to an n-th memory cell slot deployed in a first horizontal direction, wherein n is an integer greater than or equal to 2,
wherein each of the first memory cell slot to the n-th memory cell slot includes:
memory cells deployed in a second horizontal direction orthogonal to the first horizontal direction and deployed in a vertical direction;
first access lines, each of which is arranged in the vertical direction and each of which is deployed in the second horizontal direction, wherein the first access lines are determined as one type of lines among (i) wordlines connected to each of gate terminals of each of the memory cells deployed in the vertical direction and (ii) bitlines connected to each of drain terminals of each of the memory cells deployed in the vertical direction; and
second access lines, each of which is arranged in the second horizontal direction and each of which is deployed in the vertical direction, wherein the second access lines are determined as a different type of lines among (i) wordlines connected to each of the gate terminals of each of the memory cells deployed in the second horizontal direction and (ii) bitlines connected to each of the drain terminals of each of the memory cells deployed in the second horizontal direction;
wherein (i) (i-1) at least two of the first access lines among the first access lines of the first memory cell slot to the first access lines of the n-th memory cell slot deployed at their corresponding same relative second horizontal directional positions are connected to first global lines arranged in the first horizontal direction, wherein the first global lines are connected to one type of circuit elements among each of sub-wordline drivers of a first circuit array positioned below the first memory cell slot to the n-th memory cell slot and each of sense amplifiers of the first circuit array, and (i-2) the second access lines of the first memory cell slot to the second access lines of the n-th memory cell slot deployed at their corresponding same relative vertical directional positions are (i-2-1) extended to a second circuit array positioned at an outer side region of the first memory cell slot to the n-th memory cell slot and (i-2-2) connected to a different type of circuit elements among each of the sub-wordline drivers of the second circuit array and each of the sense amplifiers of the second circuit array through vias deployed in the first horizontal direction, and (ii) (ii-1) the first access lines of the first memory cell slot to the first access lines of the n-th memory cell slot deployed at their corresponding same relative second horizontal directional positions are connected to one type of circuit elements among each of the sub-wordline drivers of the first circuit array and each of the sense amplifiers of the first circuit array, and (ii-2) at least two of the second access lines among the second access lines of the first memory cell slot to the second access lines of the n-th memory cell slot deployed at their corresponding same relative vertical directional positions are (ii-2-1) extended to the second circuit array and (ii-2-2) connected to second global lines arranged in the first horizontal direction through the vias deployed in the first horizontal direction, wherein the second global lines are connected to a different type of the circuit elements among each of the sub-wordline drivers of the second circuit array and each of the sense amplifiers of the second circuit array.

2. The 3-dimensional memory device of claim 1, wherein, in case the first access lines or the second access lines are the wordlines,
each of the first global lines is (i) deployed at a side region of a first horizontal directional region on the first circuit array, which is defined by the first access lines of the first memory slot to the first access lines of the n-th memory slot deployed at their corresponding same relative second horizontal directional positions, and (ii) connected to each of corresponding said first access lines, and
each of the second global lines is (i) deployed at a side region of a first horizontal directional region on the second circuit array, which is defined by the vias corresponding to the second access lines of the first memory cell slot to the second access lines of the n-th memory cell slot deployed at their corresponding same relative vertical directional positions, and (ii) connected to each of corresponding said vias.

3. The 3-dimensional memory device of claim 1, wherein, in case the first access lines or the second access lines are the wordlines,
each of the first global lines includes (i) first body lines deployed at a side region of a first horizontal directional region on the first circuit array, which is defined by the first access lines of the first memory slot to the first access lines of the n-th memory slot deployed at their corresponding same relative second horizontal directional positions, and (ii) first contact pads extended in the second horizontal direction from each of the first body lines and connected to each of corresponding said first access lines, and
each of the second global lines includes (i) second body lines deployed at a side region of a first horizontal directional region on the second circuit array, which is defined by the second access lines of the first memory slot to the second access lines of the n-th memory slot deployed at their corresponding same relative vertical directional positions, and (ii) second contact pads extended in the second horizontal direction from each of the second body lines and connected to each of corresponding said vias.

4. The 3-dimensional memory device of claim 1, wherein, in case the first access lines or the second access lines are the wordlines,
each of the first global lines is alternately deployed at one side region and an opposite side region of a first horizontal directional region on the first circuit array, which is defined by the first access lines of the first memory slot to the first access lines of the n-th memory slot deployed at their corresponding same second relative horizontal directional positions, and
each of the second global lines is alternatively deployed at one side region and an opposite side region of a first horizontal directional region on the second circuit array, which is defined by the vias corresponding to the second access lines of the first memory cell slot to the second access lines of the n-th memory cell slot deployed at their corresponding same relative vertical directional positions.

5. The 3-dimensional memory device of claim 1, wherein, in case the first access lines or the second access lines are the bitlines,
each of the first global lines is connected directly or connected through switches to at least two first access lines among the first access lines of the first memory cell slot to the first access lines of the n-th memory cell slot deployed at their corresponding same relative second horizontal directional positions, and
each of the second global lines is connected directly or connected via the switches to at least two vias corresponding to at least two second access lines among the second access lines of the first memory cell slot to the second access lines of the n-th memory cell slot deployed at their corresponding same relative vertical directional positions.

6. The 3-dimensional memory device of claim 1, wherein, in case the first access lines or the second access lines are the bitlines,
each of the first global lines includes (i) first body lines deployed at a side region of a first horizontal directional region on the first circuit array, which is defined by the first access lines of the first memory slot to the first access lines of the n-th memory slot deployed at their corresponding same relative second horizontal directional positions, and (ii) first contact pads extended in the second horizontal direction from each of the first body lines and connected to each of corresponding said first access lines, and
each of the second global lines includes (i) second body lines deployed at a side region of a first horizontal directional region on the second circuit array, which is defined by the second access lines of the first memory slot to the second access lines of the n-th memory slot deployed at their corresponding same relative vertical directional positions, and (ii) second contact pads extended in the second horizontal direction from each of the second body lines and connected to each of corresponding said vias.

7. The 3-dimensional memory device of claim 1, wherein, in case the first access lines or the second access lines are the bitlines,
each of the first global lines is alternately deployed at one side region and an opposite side region of a first horizontal directional region on the first circuit array, which is defined by the first access lines of the first memory slot to the first access lines of the n-th memory slot deployed at their corresponding same relative second horizontal directional positions, and
each of the second global lines is alternatively deployed at one side region and an opposite side region of a first horizontal directional region on the second circuit array, which is defined by the vias corresponding to the second access lines of the first memory cell slot to the second access lines of the n-th memory cell slot deployed at their corresponding same relative vertical directional positions.

8. A 3-dimensional memory device, comprising:
a first memory cell slot to an n-th memory cell slot deployed in a first horizontal direction, wherein n is an integer greater than or equal to 2,
wherein each of the first memory cell slot to the n-th memory cell slot includes:
memory cells deployed in a second horizontal direction orthogonal to the first horizontal direction and deployed in a vertical direction;
first access lines, each of which is arranged in the vertical direction and each of which is deployed in the second horizontal direction, wherein the first access lines are determined as one type of lines among (i) wordlines connected to each of gate terminals of each of the memory cells deployed in the vertical direction and (ii) bitlines connected to each of drain terminals of each of the memory cells deployed in the vertical direction; and
second access lines, each of which is arranged in the second horizontal direction and each of which is deployed in the vertical direction, wherein the second access lines are determined as a different type of lines among (i) wordlines connected to each of the gate terminals of each of the memory cells deployed in the second horizontal direction and (ii) bitlines connected to each of the drain terminals of each of the memory cells deployed in the second horizontal direction;
wherein (i-1) at least two of the first access lines among the first access lines of the first memory cell slot to the first access lines of the n-th memory cell slot deployed at their corresponding same relative second horizontal directional positions are connected to first global lines arranged in the first horizontal direction, wherein the first global lines are connected to one type of circuit elements among each of sub-wordline drivers of a first circuit array positioned below the first memory cell slot to the n-th memory cell slot and each of sense amplifiers of the first circuit array, and (i-2) at least two of the second access lines among the second access lines of the first memory cell slot to the second access lines of the n-th memory cell slot deployed at their corresponding same relative vertical directional positions are (i-2-1) extended to a second circuit array positioned at an outer side region of the first memory cell slot to the n-th memory cell slot and (i-2-2) connected to second global lines arranged in the first horizontal direction through the vias deployed in the first horizontal direction, wherein the second global lines are connected to a different type of circuit elements among each of the sub-wordline drivers of the second circuit array and each of the sense amplifiers of the second circuit array.

9. The 3-dimensional memory device of claim 8,
wherein, in case the first access lines that are deployed at a corresponding specific same relative second horizontal directional position in the first horizontal direction, among the first access lines of the first memory cell slot to the first access lines of the n-th memory cell slot deployed at their corresponding same relative second horizontal directional positions, are defined as a (1_1)-st access line to a (1_n)-th access line,
each of the first global lines shares m first access lines, which are sequentially adjacent access lines, among the (1_1)-st access line to the (1_n)-th access line, with m being an integer greater than or equal to 2, and
wherein, in case the second access lines that are deployed at a corresponding specific same relative vertical directional position, among the second access lines of the first memory cell slot to the second access lines of the n-th memory cell slot deployed at their corresponding relative same vertical directional positions, are defined as a (2_1)-st access line to a (2_n)-th access line,
each of the second global lines shares n/m second access lines, which are sequentially m-th adjacent access lines, among the (2_1)-st access line to the (2_n)-th access line.

10. The 3-dimensional memory device of claim 9, wherein n is a multiple of m, wherein the first global lines include a (1_1)-st global line to a (1_(n/m))-th global line, wherein a (1 j)-th global line shares a (1_(1+(j−1)*m))-th access line to a (1_j*m)-th access line, with j being an integer greater than or equal to 1 and less than or equal to n/m, wherein the second global lines include a (2_1)-st global line to a (2_m)-th global line, wherein a (2_k)-th global line shares a (2_(k+(s−1)*m))-th access line, with k being an integer greater than or equal to 1 and less than or equal to m, and with s being integers greater than or equal to 1 and less than or equal to n/m.

11. The 3-dimensional memory device of claim 9, wherein n is not a multiple of m, and
(i) the first global lines include a (1_1)-st global line to a (1_[n/m])-th global line, with the [n/m] being a Gaussian function representing a maximum integer not greater than n/m, wherein, a (1_j)-th global line shares a (1_(1+(j−1)*m))-th access line to a (1_j*m)-th access line, with j being an integer greater than or equal to 1 and less than or equal to [n/m], wherein the second global lines include a (2_1)-st global line to a (2_m)-th global line, wherein a (2_k)-th global line shares a (2_(k+(s−1)*m))-th access line, with k being an integer greater than or equal to 1 and less than or equal to m, and with s being integers greater than or equal to 1 and less than or equal to [n/m], and
(ii) (ii-1) a (1_(m*[n/m]+1))-th access line to the (1_n)-th access line, which exclude the (1_1)-st access line to a (1_(m*[n/m]))-th access line among the (1_1)-st access line to the (1_n)-th access line, wherein the (1_1)-st access line to the (1_(m*[n/m]))-th access line are being shared, and (ii-2) a (2_(m*[n/m]+1))-th access line to the (2_n)-th access line, which exclude the (2_1)-st access line to a (2_(m*[n/m]))-th access line among the (2_1)-st access line to the (2_n)-th access line, wherein the (2_1)-st access line to the (2_(m*[n/m]))-th access line are being shared, are shared by using a process of (i) with m being replaced by m′ or the (1_(m*[n/m]+1))-th access line to the (1_n)-th access line and the (2_(m*[n/m]+1))-th access line to the (2_n)-th access line are not shared.

12. The 3-dimensional memory device of claim 9, wherein
each of the first global lines is formed at a lower region of the m first access lines that are sequentially adjacent, among the (1_1)-st access (1_n)-th access line, and connected to each of the m first access lines that are sequentially adjacent, and
each of the second global lines includes second body lines deployed at a lower side region of a first horizontal directional region, which is defined by a first via to an n-th via corresponding to the (2_1)-st access line to the (2_n)-th access line, and second contact pads extending in the second horizontal direction from each of the second body lines, wherein the second contact pads are connected to n/m vias, which are sequentially m-th adjacent vias, among the first via to the n-th via.

13. The 3-dimensional memory device of claim 12,
wherein, in case the first access lines are the bitlines,
each of the first global lines is formed at a lower region of the m first access lines that are sequentially adjacent, among the (1_1)-st access line to the (1_n)-th access line, and is connected directly or connected through switches to each of the m first access lines that are sequentially adjacent, and
wherein, in case the second access lines are the bitlines,
each of the second global lines is connected directly or connected through switches to each of the n/m vias, which are sequentially m-th adjacent vias, among the first via to the n-th via.

14. The 3-dimensional memory device of claim 10, wherein each of the second body lines corresponding to each of the second global lines is alternatively deployed at one side region and an opposite side region of a first horizontal directional region, which is defined by the first via to the n-th via.

15. The 3-dimensional memory device of claim 8,
wherein, in case the second access lines that are deployed at a corresponding specific same relative vertical directional position, among the second access lines of the first memory cell slot to the second access lines of the n-th memory cell slot deployed at their corresponding same relative vertical directional positions, are defined as a (2_1)-st access line to a (2_n)-th access line,
each of the second global lines shares m second access lines among the (2_1)-st access line to the (2_n)-th access line, wherein the m second access lines are sequentially adjacent access lines, with m being an integer greater than or equal to 2, and
wherein, in case the first access lines that are deployed at a corresponding specific same relative second horizontal directional position, among the first access lines of the first memory cell slot to the first access lines of the n-th memory cell slot deployed at their corresponding same relative second horizontal directional positions, are defined as a (1_1)-st access line to the (1_n)-th access line,
each of the first global lines shares n/m first access lines, which are sequentially m-th adjacent access lines, among the (1_1)-st access line to the (1_n)-th access line.

16. The 3-dimensional memory device of claim 15, wherein n is a multiple of m, wherein the second global lines include a (2_1)-st global line to a (2_(n/m))-th global line, wherein a (2_j)-th global line shares a (2 (1+(j−1)*m))-th access line to a (2_j*m)-th access line, with j being an integer greater than or equal to 1 and less than or equal to n/m, wherein the first global lines include a (1_1)-st global line to a (1_m)-th global line, wherein a (1_k)-th global line shares a (1_(k+(s−1)*m))-th access line, with k being an integer greater than or equal to 1 and less than or equal to m, and with s being integers greater than or equal to 1 and less than or equal to n/m.

17. The 3-dimensional memory device of claim 15, wherein n is not a multiple of m, and
(i) the second global lines include a (2_1)-st global line to a (2 [n/m])-th global line, with the [n/m] being a Gaussian function representing a maximum integer not greater than n/m, wherein a (2_j)-th global line shares a (1_(1+(j−1)*m))-th access line to a (1_j*m)-th access line, with j being an integer greater than or equal to 1 and less than or equal to the [n/m], wherein the first global lines include a (1_1)-st global line to a (1_m)-th global line, wherein a (1_k)-th global line shares a (1_(k+(s−1)*m))-th access line, with k being an integer greater than or equal to 1 and less than or equal to m, and with s being integers greater than or equal to 1 and less than or equal to [n/m], and
(ii) (ii-1) a (2_(m*[n/m]+1))-th access line to the (2_n)-th access line, which exclude the (2_1)-st access line to a (2_(m*[n/m]))-th access line among the (2_1)-st access line to the (2_n)-th access line, wherein the (2_1)-st access line to the (2_(m*[n/m]))-th access line are being shared, and (ii-2) a (1_(m*[n/m]+1))-th access line to the (1_n)-th access line, which exclude the (1_1)-st access line to a (1_(m*[n/m]))-th access line among the (1_1)-st access line to the (1_n)-th access line, wherein the (1_1)-st access line to the (1_(m*[n/m]))-th access line are being shared, are shared by using a process of (i) with m being replaced by m′ or the (2_(m*[n/m]+1))-th access line to the (2_n)-th access line and the (1_(m*[n/m]+1))-th access line to the (1_n)-th access line are not shared.

18. The 3-dimensional memory device of claim 15, wherein
each of the second global lines is formed at a lower region of m vias that are sequentially adjacent, among a first via to an n-th via corresponding to the (2_1)-st access line to the (2_n)-th access line, and connected to each of the m vias that are sequentially adjacent, and
each of the first global lines includes first body lines formed at a lower side region of a first horizontal directional region, which is defined by the (1_1)-st access line to the (1_n)-th access line, and first contact pads extending in the second horizontal direction from each of the first body lines, wherein the first contact pads are connected to the n/m first access lines, which are sequentially m-th adjacent access lines, among the (1_1)-st access line to the (1_n)-th access line.

19. The 3-dimensional memory device of claim 18,
wherein, in case the second access lines are the bitlines,
each of the second global lines is formed at a lower region of the m vias that are sequentially adjacent, among the first via to the n-th via, and is connected directly or connected through switches to each of the m vias that are sequentially adjacent, and
wherein, in case the first access lines are the bitlines,
each of the first global lines is connected directly or connected through switches to each of the n/m first access lines, which are sequentially m-th adjacent access lines, among the (1_1)-st access line to the (1_n)-th access line.

20. The 3-dimensional memory device of claim 18, wherein each of the first body lines corresponding to each of the first global lines is alternatively deployed at one side region and an opposite side region of the first horizontal directional region, which is defined by the (1_1)-st access line to the (1_n)-th access line.
